(19) United States
(12) Patent Application Publication
(10) Pub. No.: US 2026/0319619 A1
(43) Pub. Date: Oct. 15, 2026

(54) INTEGRATED CIRCUIT AND SENSOR CONTROLLER

(71) Applicant: Wacom Co., Ltd., Saitama (JP)

(72) Inventors: Hiroshi MIZUHASHI, Saitama (JP); Fumitaka GOTO, Saitama (JP); Masaya YAMADA, Saitama (JP)

(73) Assignee: Wacom Co., Ltd., Saitama (JP)

(21) Appl. No.: 19/676,574

(22) Filed: May 13, 2026

Related U.S. Application Data
(63) Continuation of application No. PCT/JP2024/040595, filed on Nov. 15, 2024.

(30) Foreign Application Priority Data
Nov. 20, 2023 (JP) 2023-196599
Nov. 22, 2023 (JP) 2023-198236
Oct. 4, 2024 (JP) 2024-174806

(51) Int. Cl. G06F 3/041; G06F 3/0354; G06F 3/046

(52) U.S. Cl. CPC G06F 3/04184; G06F 3/03545; G06F 3/04164; G06F 3/046

(57) ABSTRACT

An integrated circuit is capable of switching between multiple connection methods to connect a reception coil of an EMR sensor and a sensor controller. An integrated circuit is a switch circuit connected with a plurality of loop coils LCx constituting a reception coil of an EMR sensor. The plurality of loop coils LCx have a plurality of ends such as ends T12 and T21 along a first side of a touch surface. The switch circuit includes a differential amplifier that has a non-inverting input terminal and an inverting input terminal, and a switch group that switches a connection destination of the end T12 between the inverting input terminal of the differential amplifier, the end T21, a ground terminal, and the non-inverting input terminal of the differential amplifier.

### BACKGROUND

### Technical Field

The present disclosure relates to an integrated circuit and a sensor controller, and particularly to an integrated circuit and a sensor controller for use with an electromagnetic resonance (EMR) sensor.

### Description of the Related Art

An EMR method is known for the detection of a position of an electromagnetic resonance pen inside a panel surface of a tablet or the like. A position detection device using the EMR method includes a sensor for detecting a pen disposed inside the panel surface (hereinafter referred to as an “EMR sensor”), and a sensor controller connected with the EMR sensor. The EMR sensor has transmission coils including a plurality of Tx coils arranged side by side in a y-direction, and reception coils including a plurality of Rx coils arranged side by side in an x-direction. The plurality of Tx coils sequentially send alternating magnetic fields, and the respective Rx coils receive a reflection signal transmitted from the electromagnetic resonance pen (hereinafter referred to as a “pen signal”) for each time. In this manner, the sensor controller detects a position of the electromagnetic resonance pen (hereinafter referred to as a “pen position”), and receives data transmitted from the electromagnetic resonance pen (hereinafter referred to as “pend data”). Each of Patent Documents 1 to 3 discloses an example of the EMR sensor.

Patent Document 2 discloses an example of an EMR sensor which uses loop coils as the Rx coils. Both ends of each of the Rx coils disclosed in Patent Document 2 are respectively connected with two input terminals of a differential amplifier which outputs pen signals. Patent Document 3 discloses an example of an EMR sensor which uses straight electrodes (hereinafter referred to as “linear electrodes”) instead of the Rx coils.

### PRIOR ART DOCUMENT

### Patent Document

Patent Document 1: Japanese Patent No. 6698386

Patent Document 2: JP 2018-185559A

Patent Document 3: JP 2022-117491A

### BRIEF SUMMARY

### Technical Problem

Meanwhile, several connection methods achieve connection between the sensor controller and the respective Rx coils constituting the reception coils of the EMR sensor. Specifically, these methods include a differential method which connects both ends of each Rx coil with the sensor controller, a single-end method which connects one end of each Rx coil with the sensor controller, and grounds the other end, and a batch input method which connects the plurality of Rx coils with the sensor controller in series, for example. Each of these methods has its own advantages but the method allowed to be used by each conventional position detection device is limited to only one of these. Accordingly, there has been a demand for developing a technology capable of switching the method for connection between the respective Rx coils and the sensor controller.

The present disclosure provides an integrated circuit capable of switching methods for connection between reception coils of an EMR sensor and a sensor controller.

Coils constituting the reception coils of the EMR sensor and a coil (hereinafter referred to as a “comb-shaped coil”) which includes a large number of wires (hereinafter referred to as “comb portions” or “teeth”) extending in the y-direction and connected with one wire (hereinafter referred to as a “base portion”) extending in the x-direction, instead of the plurality of Rx coils described above, are provided. One end of each of the comb portions is connected with the base portion, while the other end is connected with the sensor controller. The sensor controller, which receives pen signals from the other ends of the two adjoining comb portions considering these ends as both ends of an Rx coil, can achieve reception of pen signals in a manner similar to the manner of reception of pen signals by an Rx coil which is formed by two comb portions and a section included in the base portion and connecting these comb portions, even though each of the two comb portions is actually connected with a different comb portion via the base portion. Accordingly, the pen position is detectable by using the comb-shaped coil similarly to the case of use of the plurality of Rx coils.

However, the comb-shaped coil has a drawback of low detection accuracy of the pen position. This drawback comes from the configuration of the comb-shaped coil, which is considered to be equivalent to virtual loop coils each formed by two adjoining comb portions, and arranged with clearances left between the respective loop coils in the x-direction.

Accordingly, the present disclosure further provides an integrated circuit capable of increasing detection accuracy of a pen position achieved with use of a comb-shaped coil as reception coils of an EMR sensor.

In addition, alternating magnetic fields appear in the Rx coils during sending of these fields from the Tx coils. Accordingly, the sensor controller stops sending of the alternating magnetic fields from the Tx coils before reception of pen signals by the Rx coils. However, an influence of a time constant of the Rx coils remains in the Rx coils even after the sending of the alternating magnetic fields from the Tx coils has stopped. In this case, a signal to noise ratio (SNR) of the pen signals deteriorates.

Accordingly, the present disclosure further provides an integrated circuit and a sensor controller capable of improving the SNR of pen signals.

Furthermore, coils constituting the reception coils of the EMR sensor and a coil (hereinafter referred to as a “comb-shaped coil”) which includes a large number of wires (hereinafter referred to as “comb portions”) extending in the y-direction and connected with one wire (hereinafter referred to as a “base portion”) extending in the x-direction, instead of the plurality of Rx coils described above, are provided. One end of each of the comb portions is connected with the base portion, while the other end is connected with the sensor controller. The sensor controller, which receives pen signals from the other ends of the two adjoining comb portions considering these ends as both ends of an Rx coil, can achieve reception of pen signals in a manner similar to the manner of reception of pen signals by an Rx coil which is formed by two comb portions and a section included in the base portion and connecting these comb portions, even though each of the two comb portions is actually connected with a different comb portion via the base portion. Accordingly, the pen position is detectable by using the comb-shaped coil similarly to the case of use of the plurality of Rx coils.

However, the comb-shaped coil has a drawback of low detection accuracy of the pen position. This drawback comes from the configuration of the comb-shaped coil, which is considered to be equivalent to virtual loop coils each formed by two adjoining comb portions, and arranged with clearances left between the respective loop coils in the x-direction.

Accordingly, the present disclosure further provides an integrated circuit and a sensor controller capable of increasing detection accuracy of the pen position achieved with use of a comb-shaped coil as reception coils of an EMR sensor.

In addition, in a configuration adopting linear electrodes instead of the Rx coils as described in Patent Document 2, pen signals have opposite signs for the linear electrodes located on one side in the x-direction as viewed from the pen position and for the linear electrodes located on the opposite side in the x-direction. In this case, a problem of low pen signal reception intensity may be caused near the pen position as a result of a change of signs of pen signals near the pen position.

Accordingly, the present disclosure further provides an integrated circuit and a sensor controller capable of increasing pen signal reception intensity achieved with use of linear electrodes instead of Rx coils.

Moreover, for conventional position detection devices, a tilt of the electromagnetic resonance pen with respect to the panel surface may cause a deviation of a peak position of pen signals received by the Rx coils from an original pen tip position, depending on an azimuth angle of the electromagnetic resonance pen. This deviation may lower detection accuracy of the pen position, and therefore improvement in this point has been demanded.

Accordingly, the present disclosure further provides a sensor controller capable of accurately detecting a position of an electromagnetic resonance pen even when the pen is tilted with respect to a panel surface.

Furthermore, displays of types configured to be foldable (foldable displays) have been released in recent years. For these foldable displays, position detection of the electromagnetic resonance pen has also been demanded. However, foldable displays have a conductive hinge part to enable folding, and magnetic fields can be disturbed by the presence of this hinge part. In this case, a problem of low pen signal reception intensity may be caused near the hinge part, i.e., near a folding line.

Accordingly, the present disclosure further provides an integrated circuit and a sensor controller capable of increasing pen signal reception intensity near a folding line of a foldable display.

### Technical Solution

An integrated circuit according to a first aspect of the present disclosure is directed to an integrated circuit connected with a reception coil of an EMR sensor, in which the reception coil has a plurality of ends along a first side of a touch surface, and the plurality of ends include a first end and a second end, the integrated circuit including a differential amplifier that has a first input terminal and a second input terminal, and a switch group that switches a connection destination of the first end between the second input terminal, the second end, a ground terminal, and the first input terminal.

An integrated circuit according to a second aspect of the present disclosure is the integrated circuit according to the first aspect, in which the reception coil is a comb-shaped coil that has the plurality of ends, and the switch group switches between a first state for connecting the first end with the second input terminal and a second state for connecting the first end with the first input terminal, in a time-division manner.

An integrated circuit according to a third aspect of the present disclosure is directed to an integrated circuit connected with an EMR sensor, in which a reception coil of the EMR sensor has a plurality of first loop coils, the integrated circuit including a plurality of differential amplifiers each of which has a first input terminal and a second input terminal, a first wire that connects one end of each of the plurality of first loop coils with the first input terminal of the corresponding differential amplifier, a second wire that connects another end of each of the plurality of first loop coils with the second input terminal of the corresponding differential amplifier, and a first switch element provided between a power source wire to which predetermined power source potential is supplied, and the first wire.

A sensor controller according to a third aspect of the present disclosure is directed to a sensor controller connected with the EMR sensor via the integrated circuit according to the first aspect of the present disclosure. The plurality of first loop coils each extend in a first direction and are arranged side by side in a second direction crossing the first direction, and a transmission coil of the EMR sensor has a plurality of second loop coils each extending in the second direction and are arranged side by side in the first direction. The integrated circuit further includes a switch circuit configured to switch between a first state for connecting one end and the other end of the (2n−1)-th (n is a natural number) first loop coil from one end side in the second direction in the plurality of first loop coils with the first input terminal and the second input terminal of the corresponding differential amplifier, respectively, and disconnecting one end and the other end of the 2n-th first loop coil from the first input terminal and the second input terminal of the corresponding differential amplifier, respectively, a second state for connecting the one end and another end of the 2n-th first loop coil from the one end side in the second direction in the plurality of first loop coils with the first input terminal and the second input terminal of the corresponding differential amplifier, respectively, and disconnecting the one end and the other end of the (2n−1)-th first loop coil from the first input terminal and the second input terminal of the corresponding differential amplifier, respectively. A current is sequentially supplied to each of the plurality of second loop coils to send alternating magnetic fields from the EMR sensor, and the switch circuit is brought into the first state at the time of supply of the current to the (2m−1)-th (m is a natural number) second loop coil from one end side in the first direction in the plurality of second loop coils, and into the second state at the time of supply of the current to the 2m-th loop coil from the one end side in the first direction in the plurality of loop coils to receive a pen signal output from each of the plurality of differential amplifiers.

An integrated circuit according to a fourth aspect of the present disclosure is directed to an integrated circuit connected with an EMR sensor, in which a reception coil of the EMR sensor is a comb-shaped coil that includes a plurality of comb portions each extending in a first direction and having one end connected with a base portion extending in a second direction crossing the first direction. The integrated circuit includes a plurality of differential amplifiers each of which has a first input terminal and a second input terminal, and a switch circuit configured to switch between a first state for connecting another end of the (2n−1)-th (n is a natural number) comb portion and another end of the 2n-th comb portion from one end side in the second direction in the plurality of comb portions, with the first input terminal and the second input terminal of the same differential amplifier, respectively, and a second state for connecting the other end of the 2n-th comb portion and the other end of the 2(n+1)-th comb portion from one end side from the one end side in the second direction in the plurality of comb portions, with the first input terminal and the second input terminal of the same differential amplifier, respectively.

A sensor controller according to a fourth aspect of the present disclosure is directed to a sensor controller connected with the EMR sensor via the integrated circuit according to the second aspect of the present disclosure. A transmission coil of the EMR sensor has a plurality of loop coils each extending in the second direction and are arranged side by side in the first direction, and a current is sequentially supplied to each of the plurality of loop coils to send alternating magnetic fields from the EMR sensor. The switch circuit is brought into the first state at the time of supply of the current to the (2m−1)-th (m is a natural number) loop coil from the one end side in the first direction in the plurality of loop coils, and into the second state at the time of supply of the current to the 2m-th loop coil from the one end side in the first direction in the plurality of loop coils to receive a pen signal output from each of the plurality of differential amplifiers.

An integrated circuit according to a fifth aspect of the present disclosure is directed to an integrated circuit connected with an EMR sensor. A reception coil of the EMR sensor includes a plurality of linear electrodes each extending in a first direction and are arranged side by side in a second direction crossing the first direction, and the integrated circuit includes a plurality of differential amplifiers, each of which has a first input terminal and a second input terminal, and a wire that connects an end of the (2n−k)-th (k is an odd natural number, n is a natural number larger than k/2) linear electrode and an end of the 2n-th linear electrode from one end side in the second direction in the plurality of linear electrodes, with the first input terminal and the second input terminal of the same differential amplifier, respectively.

A sensor controller according to a fifth aspect of the present disclosure is directed to a sensor controller connected with the EMR sensor via the integrated circuit according to the third aspect of the present disclosure. A transmission coil of the EMR sensor has a plurality of loop coils each extending in the second direction and are arranged side by side in the first direction, and a current is sequentially supplied to each of the plurality of loop coils to send alternating magnetic fields from the EMR sensor. The switch circuit is brought into the first state at the time of supply of the current to the (2m−1)-th (m is a natural number) loop coil from one end side in the first direction in the plurality of loop coils, and into the second state at the time of supply of the current to the 2m-th loop coil from the one end side in the first direction in the plurality of loop coils to receive a pen signal output from each of the plurality of differential amplifiers.

A sensor controller according to a sixth aspect of the present disclosure is directed to a sensor controller connected with an EMR sensor including a plurality of loop coils. The sensor controller is configured to calculate a sum, with different weights, of a pen signal received by a first loop coil included in the plurality of loop coils, and a pen signal received by one or more different loop coils located near the first loop coils in the plurality of loop coils, and to derive a position of an electromagnetic resonance pen on the basis of a summed pen signal obtained by the summation.

An integrated circuit according to a seventh aspect of the present disclosure is directed to an integrated circuit connected with an EMR sensor. A reception coil of the EMR sensor is a comb-shaped coil that includes a plurality of comb portions each extending in a first direction and having one end connected with a base portion extending in a second direction crossing the first direction. The integrated circuit includes a reception circuit for receiving a pen signal transmitted from an electromagnetic resonance pen and a selection circuit that selects two of the plurality of comb portions and connects the two selected comb portions with the reception circuit, in which the plurality of comb portions have first to fourth comb portions sequentially from one end side in the second direction. The selection circuit carries out the selection such that a first state for selecting the first and third comb portions and a second state for selecting the second and fourth comb portions sequentially appear, each of a distance between the first comb portion and the third comb portion, and a distance between the second comb portion and the fourth comb portion corresponds to a first distance, and a distance between the first comb portion and the second comb portion is a second distance shorter than the first distance.

A sensor controller according to a seventh aspect of the present disclosure is directed to a sensor controller connected with the EMR sensor via the integrated circuit according to the seventh aspect of the present. In the integrated circuit, the plurality of comb portions includes a fifth comb portion on the opposite side of the fourth comb portion in the second direction, and the selection circuit carries out the selection such that the first state, the second state, and a third state for selecting the third and fifth comb portions sequentially appear. The sensor controller controls the selection circuit such that the first state, the second state, and the third state sequentially appear.

According to the first aspect of the present disclosure, a connection method between the reception coil of the EMR sensor and the sensor controller is switchable by controlling the switch group.

According to the second aspect of the present disclosure, reception of pen signals in the first state and reception of pen signals in the second state can be achieved in a time-division manner. In this case, each clearance between virtual loop coils can be reduced to substantially no clearance. Accordingly, improvement of detection accuracy of a pen position with use of a comb-shaped coil as the reception coil of the EMR sensor is achievable.

According to the third aspect of the present disclosure, each of the first loop coils can be pre-charged by turning on the first switch element. Accordingly, an influence of alternating magnetic fields sent from the transmission coil can be eliminated from the reception coil, and the SNR of pen signals can be improved.

According to the fourth aspect of the present disclosure, reception of pen signals in the first state and reception of pen signals in the second state can be achieved in a time-division manner. In this case, each clearance between virtual loop coils can be reduced to substantially no clearance. Accordingly, improvement of detection accuracy of a pen position with use of a comb-shaped coil as the reception coil of the EMR sensor is achievable.

According to the fifth aspect of the present disclosure, pen signals having opposite signs are mutually boosted by the differential amplifiers. Accordingly, pen signal reception intensity achieved with use of linear electrodes as Rx coils can be raised near the pen position.

According to the sixth aspect of the present disclosure, the position of the electromagnetic resonance pen is derived on the basis of the summed pen signal obtained by summing pen signals received by the plurality of loop coils with different weights. Accordingly, the position of the electromagnetic resonance pen is accurately detectable even if the electromagnetic resonance pen is tilted with respect to a panel surface.

According to the seventh aspect of the present disclosure, a virtual loop coil is shifted at intervals of a distance shorter than a distance between two comb portions constituting the virtual loop coil. Accordingly, pen signal reception intensity near a folding line of a foldable display can be raised.

### BRIEF DESCRIPTION OF THE SEVERAL VIEWS OF THE DRAWINGS

FIG. 1 is a diagram illustrating a configuration of a position detection system 1 according to a first embodiment of the present disclosure.

FIG. 2 is a diagram illustrating an internal configuration of a switch circuit 30 illustrated in FIG. 1, and a state of the switch circuit 30 using a differential method.

FIG. 3 is a diagram illustrating an internal configuration of the switch circuit 30 illustrated in FIG. 1, and a state of the switch circuit 30 using a single-end method.

FIG. 4 is a diagram illustrating an internal configuration of the switch circuit 30 illustrated in FIG. 1, and a first state of the switch circuit 30 using a batch input method.

FIG. 5 is a diagram illustrating an internal configuration of the switch circuit 30 illustrated in FIG. 1, and a second state of the switch circuit 30 using the batch input method.

FIG. 6 is a diagram illustrating a configuration of the position detection system 1 according to a second embodiment of the present disclosure.

FIG. 7 is a diagram illustrating an internal configuration and a first state of the switch circuit 30 illustrated in FIG. 6.

FIG. 8 is a diagram illustrating an internal configuration and a second state of the switch circuit 30 illustrated in FIG. 6.

FIG. 9 is a diagram illustrating a first state of the switch circuit 30 according to a first modification of the second embodiment of the present disclosure.

FIG. 10 is a diagram illustrating a second state of the switch circuit 30 according to the first modification of the second embodiment of the present disclosure.

FIG. 11 is a diagram illustrating a first state of the switch circuit 30 according to a second modification of the second embodiment of the present disclosure.

FIG. 12 is a diagram illustrating a second state of the switch circuit 30 according to the second modification of the second embodiment of the present disclosure.

FIG. 13 is a diagram illustrating an internal configuration of the switch circuit 30 according to a third embodiment of the present disclosure.

FIG. 14 is a diagram illustrating waveforms of signals and the like associated with control of switch elements S1, S2, T1, and T2 illustrated in FIG. 13.

FIGS. 15A and 15B are diagrams illustrating a driving method of an EMR sensor according to a modification of the third embodiment of the present disclosure.

FIG. 16 is a diagram illustrating a configuration of the position detection system 1 according to a fourth embodiment of the present disclosure.

FIG. 17 is a diagram illustrating an internal configuration and a first state of the switch circuit 30 illustrated in FIG. 16.

FIG. 18 is a diagram illustrating an internal configuration and a second state of the switch circuit 30 illustrated in FIG. 16.

FIGS. 19A and 19B are diagrams illustrating a driving method of an EMR sensor according to a modification of the fourth embodiment of the present disclosure.

FIG. 20 is a diagram illustrating a configuration of the position detection system 1 according to a fifth embodiment of the present disclosure.

FIG. 21 is a diagram illustrating an internal configuration and a first state of the switch circuit 30 illustrated in FIG. 20.

FIG. 22 is a diagram illustrating an internal configuration and a second state of the switch circuit 30 illustrated in FIG. 20.

FIG. 23 is a diagram illustrating simulation results of pen signal reception intensity.

FIG. 24 is a diagram illustrating an internal configuration and a first state of the switch circuit 30 included in the position detection system 1 according to a first modification of the fifth embodiment of the present disclosure.

FIG. 25 is a diagram illustrating an internal configuration and a second state of the switch circuit 30 included in the position detection system 1 according to a first modification of the fifth embodiment of the present disclosure.

FIGS. 26A and 26B are diagrams illustrating a driving method of an EMR sensor according to a second modification of the fifth embodiment of the present disclosure.

FIG. 27 is a diagram illustrating receiving pen signals with use of the position detection system 1 according to the third embodiment of the present disclosure.

FIG. 28 is a diagram for explaining an azimuth angle θ and a tilt angle Φ used in FIG. 27.

FIG. 29A is a diagram for explaining a process performed by a sensor controller 31 according to a sixth embodiment of the present disclosure, while FIG. 29B is a diagram illustrating a virtual loop coil VLCx obtained by summation illustrated in FIG. 29A.

FIG. 30 is a diagram illustrating reception levels of a summed pen signal PS_{SUM} in a case where the pen tip of an electromagnetic resonance pen 2 is located at the position of an x-coordinate of 0 mm.

FIG. 31A is a plan view of an EMR sensor 33 included in a position detection device 3 according to a seventh embodiment of the present disclosure, while FIG. 31B is a cross-sectional view of the EMR sensor 33 taken along a line A to A indicated in FIG. 31A.

FIG. 32A is a diagram collectively illustrating distributions of reception levels of pen signals PS received in cases where the pen tip of the electromagnetic resonance pen 2 is located at respective positions in an x-direction on an assumption that the position detection device 3 according to the seventh embodiment of the present disclosure adopts an ODD/EVEN method, while FIG. 32B is a diagram collectively illustrating distributions of reception levels of the pen signals PS received in cases where the pen tip of the electromagnetic resonance pen 2 is located at respective positions in the x-direction for the position detection device 3 of the seventh embodiment of the present disclosure (i.e., the position detection device 3 adopting an A/B/C method).

FIG. 33 is a diagram illustrating an internal configuration and a first state of the switch circuit 30 according to the seventh embodiment of the present disclosure.

FIG. 34 is a diagram illustrating an internal configuration and a second state of the switch circuit 30 according to the seventh embodiment of the present disclosure.

FIG. 35 is a diagram illustrating an internal configuration and a third state of the switch circuit 30 according to the seventh embodiment of the present disclosure.

FIG. 36 is a diagram plotting maximum values of the reception levels of the pen signals PS observed by adoption of the ODD/EVEN method, and maximum values of the reception levels of the pen signals PS observed by adoption of the A/B/C method, for each distance (pen height) to the pen tip of the electromagnetic resonance pen 2 from a touch surface 3a.

FIG. 37 is a diagram for explaining a process performed by the sensor controller 31 according to a modification of the seventh embodiment of the present disclosure.

### DETAILED DESCRIPTION

Embodiments of the present disclosure will be hereinafter described in detail with reference to the accompanying drawings.

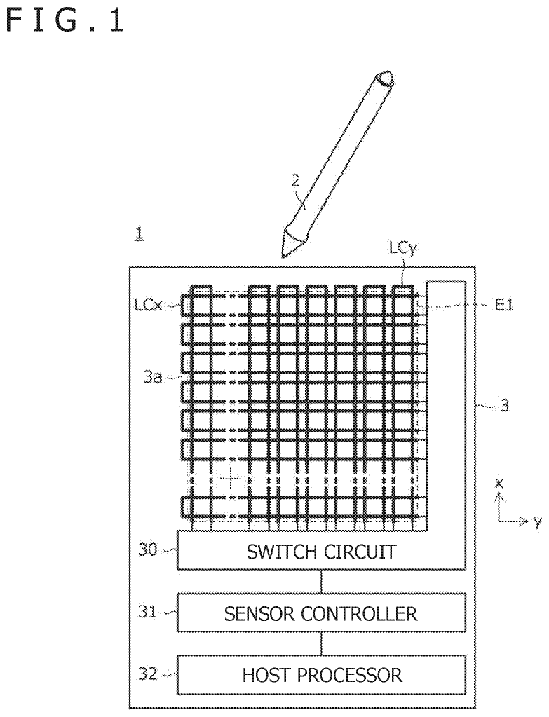

FIG. 1 is a diagram illustrating a configuration of a position detection system 1 according to a first embodiment of the present disclosure. As illustrated in the figure, the position detection system 1 includes an electromagnetic resonance pen 2 and a position detection device 3. The electromagnetic resonance pen 2 of the position detection system 1 is a pen capable of achieving position detection by the EMR method, and includes a resonant circuit containing coils and capacitors inside.

The position detection device 3 is a device configured to detect a position of the electromagnetic resonance pen 2 inside a touch surface 3a (panel surface) by using the EMR method. A plurality of loop coils LCx (Rx coils) and a plurality of loop coils LCy (Tx coils) corresponding to reception coils and transmission coils of an EMR sensor, respectively, are arranged inside the touch surface 3a. The position detection device 3 further includes a switch circuit 30, a sensor controller 31, and a host processor 32. A typical example of the position detection device 3 is a tablet or a laptop computer which has a display surface also functioning as the touch surface 3a, but the position detection device 3 may be constituted by a digitizer having no display surface.

An x-direction and a y-direction illustrated in the figure are directions both defined inside the touch surface 3a, and cross each other at right angles. The plurality of loop coils LCx are each so formed as to extend in the y-direction, and are arranged side by side in the x-direction. Meanwhile, the plurality of loop coils LCy are each so formed as to extend in the x-direction, and are arranged side by side in the y-direction. Note that each of the loop coils LCx and LCy may be overlapped with the adjoining different loop coil LCx or LCy. In this case, the overlapping loop coils are three-dimensionally formed with use of via conductors or the like. Both ends of each of the loop coils LCx and the loop coils LCy are connected with the switch circuit 30. The ends of the respective loop coils LCx are arranged along a side E1 constituting one side of the touch surface 3a having a rectangular shape.

The switch circuit 30 is a switch assembly (switch groups) which includes a plurality of switches for switching mutual connection between the plurality of loop coils LCx, and connection between the plurality of loop coils LCx and LCy and the sensor controller 31. The switch circuit 30 may constitute an integrated circuit alone, or may be provided inside an integrated circuit identical to an integrated circuit containing the sensor controller 31. The switching status of the switch circuit 30 is controlled by the sensor controller 31.

The sensor controller 31 is an integrated circuit which has a function of detecting a position of the electromagnetic resonance pen 2 (pen position) inside the touch surface 3a by the EMR method. The sensor controller 31 controls the status of connection with the loop coils LCx and LCy by controlling the switch circuit 30 to perform a process for sequentially supplying alternating current to each of the plurality of loop coils LCy, and receiving pen signals generated in the respective loop coils LCx for each supply. Besides, the sensor controller 31 is configured to derive the pen position on the basis of the pen signals thus received, and receive pen data transmitted from the electromagnetic resonance pen 2.

Specifically, when the sensor controller 31 starts supply of alternating current to any one of the loop coils LCy, the corresponding loop coil LCy starts sending of an alternating magnetic field. When a coil of the electromagnetic resonance pen 2 enters this alternating magnetic field, electromotive force is generated at both ends of this coil, and a capacitor of the electromagnetic resonance pen 2 is charged. Subsequently, when the sensor controller 31 stops supply of alternating current to the loop coil LCy, an alternating magnetic field (pen signal) is sent from the coil of the electromagnetic resonance pen 2 according to power accumulated in the capacitor of the electromagnetic resonance pen 2.

Note herein that the electromagnetic resonance pen 2 is configured to transmit pen data, such as a writing pressure value indicating pressure applied to the pen tip, and on-off information indicating the on-off state of a switch provided on the surface, by using pen signals. Specifically, the capacitor constituting the resonant circuit of the electromagnetic resonance pen 2 is configured to change capacitance according to values of the pen data. When the capacitance of the capacitor changes, the resonance frequency of the resonant circuit changes according to the amount of this change. Accordingly, the frequency of the alternating magnetic field sent from the coil changes according to the values of the pen data. The electromagnetic resonance pen 2 is configured to achieve frequency modulation of the alternating magnetic field sent from the coil according to the pen data by utilizing this characteristic of the resonant circuit.

The pen signals sent from the coil of the electromagnetic resonance pen 2 are received by the respective loop coils LCx. The sensor controller 31 allows the respective loop coils LCx to receive the pen signals for each supply of alternating current while changing the loop coil LCy to which alternating current is supplied by controlling the switch circuit 30. In this manner, the sensor controller 31 acquires intensity of the pen signals for each combination of the loop coil LCy and the loop coil LCx. Thereafter, the sensor controller 31 derives an intensity distribution of the pen signals inside the touch surface 3a on the basis of the respective levels of the acquired intensity, and detects a vertex of this distribution as the pen position. Moreover, the sensor controller 31 detects a change of the frequency of the pen signal received with the highest intensity to acquire pen data. The sensor controller 31 is configured to supply the detected position and the acquired data in the manner described above to the host processor 32 for each detection and acquisition of the position and data.

Note herein that detection of the pen position by the sensor controller 31 is executed in either one of two modes of global scanning and local scanning. Global scanning is a process executed when the detected pen position is still absent. The sensor controller 31 carries out a series of the processes described above by using all of the loop coils LCx and LCy. In this manner, the sensor controller 31 is allowed to detect the electromagnetic resonance pen 2 throughout the touch surface 3a.

Meanwhile, local scanning is a process executed in a case where any pen position already detected is present. In this case, the sensor controller 31 carries out a series of the processes described above by using only the loop coils LCx and LCy located near the pen position previously detected. In this manner, the time required for one position detection can be reduced. Accordingly, the sensor controller 31 is allowed to detect the pen position more frequently than in the case of global scanning.

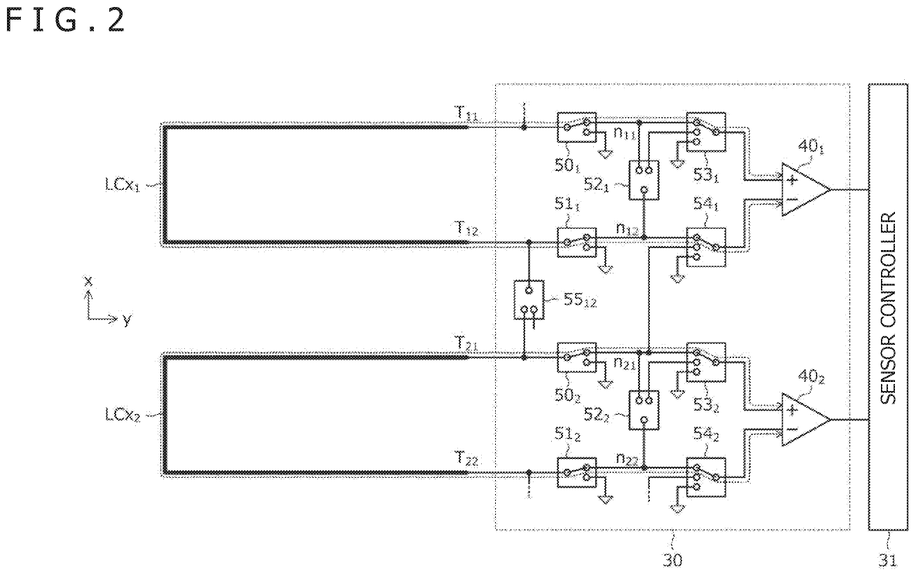

Moreover, the sensor controller 31 is configured to select any one of the differential method, the single-end method, and the batch input method described above for reception of the pen signals by the respective loop coils LCx. This selection may be conducted in a manufacturing stage of the sensor controller 31 or the position detection device 3, or during use by a user. For example, the sensor controller 31 may select the batch input method in a case where the writing pressure value contained in the latest pen data already received indicates that the electromagnetic resonance pen 2 is currently in a hovering state (a state of no contact between the pen tip and the touch surface 3a), and may select the differential method or the single-end method in a case where the writing pressure value indicates that the electromagnetic resonance pen 2 is currently in a pen touch state (a state of contact between the pen tip and the touch surface 3a). The sensor controller 31 controls the switch circuit 30 according to a result of the selection, thereby achieving reception of the pen signals by using the selected method. Specific control performed by the sensor controller 31 for the switch circuit 30 will be discussed in detail below with reference to FIGS. 2 to 5.

The host processor 32 is a central processing device included in the position detection device 3 to perform a function of implementing an operating system of the position detection device 3 and various applications by executing programs read from a not-illustrated memory. Processes executed by the host processor 32 under the programs include various processes performed on the basis of the pen position and the pen data supplied from the sensor controller 31. For example, the respective processes noted herein include movement of a cursor indicated on the display surface, generation of stroke data indicating trajectory of the electromagnetic resonance pen 2 inside the touch surface, and others. For the stroke data in these processes, the host processor 32 also carries out a process for rendering and displaying the generated stroke data, a process for generating digital ink containing the generated stroke data and recording the digital ink, a process for transmitting the generated digital ink to an external device in accordance with an instruction from the user, and other processes.

FIGS. 2 to 5 are diagrams illustrating an internal configuration of the switch circuit 30. These figures illustrate only a part associated with reception of pen signals by the respective loop coils LCx in the internal configuration of the switch circuit 30. Described below in detail with reference to these figures will be the internal configuration of the switch circuit 30, and specific control performed by the sensor controller 31 for the switch circuit 30 to implement each of the differential method, the single-end method, and the batch input method.

In addition, needless to say, the position detection device 3 in actual situations has a larger number of the loop coils LCx than the only two loop coils LCx₁ and LCx₂ illustrated in FIGS. 2 to 5 for simplifying the explanation. Hereinafter, one and the other ends of the loop coil LCx₁ will be referred to as ends T₁₁ and T₁₂, and one and the other ends of the loop coil LCx₂ will be referred to as ends T₂₁ and T₂₂, respectively.

Initially referring to FIG. 2, the switch circuit 30 includes a plurality of differential amplifiers 40, and switch groups each including a plurality of switches 50 to 55. The one differential amplifier 40 is provided for each of the loop coils LCx. Each of the switches 50, 51, and 52 is a single-pole double-throw switch, while each of the switches 53 and 54 is a single-pole triple-throw switch. The respective switches 50 to 54 are provided for each of the loop coils LCx. Meanwhile, the switch 55 is a single-pole double-throw switch, and provided for each set of the two adjoining loop coils LCx. In the following explanation, a subscript “1” will be given to the right side of a symbol of a configuration corresponding to the loop coil LCx₁, a subscript “2” will be given to the right side of a symbol of a configuration corresponding to the loop coil LCx₂, and a subscript “12” will be given to the right side of a symbol of a configuration corresponding to both the loop coils LCx₁ and LCx₂, as necessary in some cases to distinguish these configurations from other configurations.

Each of the differential amplifiers 40 is an amplifier circuit (differential amplifier) which has a non-inverting input terminal, an inverting input terminal, and an output terminal, and is configured to amplify a potential difference between the non-inverting input terminal and the inverting input terminal, and output the amplified potential difference from the output terminal as an output voltage for the ground potential. The output signals of the respective differential amplifiers 40 are supplied to the sensor controller 31 as pen signals.

The switch 50₁ is configured as follows: a common terminal is connected with the terminal T₁₁; one selection terminal is connected with the ground terminal; and the other selection terminal constitutes a node n₁₁ illustrated in the figure. The switch 51₁ is configured as follows: a common terminal is connected with the terminal T₁₂; one selection terminal is connected with the ground terminal; and the other selection terminal constitutes a node n₁₂ illustrated in the figure. The switch 52₁ is configured as follows: a common terminal is connected with the node n₁₂; one selection terminal is connected with the node n₁₁; and the other selection terminal is connected with a second selection terminal of the switch 53₁. The switch 53₁ is configured as follows: a common terminal is connected with the non-inverting input terminal of the differential amplifier 40₁; a first selection terminal is connected with the node n₁₁; and a third selection terminal is connected with the ground terminal. The switch 54₁ is configured as follows: a common terminal is connected with the inverting input terminal of the differential amplifier 40₁; a first selection terminal is connected with the node n₁₂; a second selection terminal is connected with a node n₂₁ described below; and a third selection terminal is connected with the ground terminal.

The switch 50₂ is configured as follows: a common terminal is connected with the terminal T₂₁; one selection terminal is connected with the ground terminal; and the other selection terminal constitutes the node n₂₁ illustrated in the figure. The switch 51₂ is configured as follows: a common terminal is connected with the terminal T₂₂; one selection terminal is connected with the ground terminal; and the other selection terminal constitutes a node n₂₂ illustrated in the figure. The switch 52₂ is configured as follows: a common terminal is connected with the node n₂₂; one selection terminal is connected with the node n₂₁; and the other selection terminal is connected with a second selection terminal of the switch 53₂. The switch 53₂ is configured as follows: a common terminal is connected with the non-inverting input terminal of the differential amplifier 40₂; a first selection terminal is connected with the node n₂₁; and a third selection terminal is connected with the ground terminal. The switch 54₂ is configured as follows: a common terminal is connected with the inverting input terminal of the differential amplifier 40₂; a first selection terminal is connected with the node n₂₂; and a third selection terminal is connected with the ground terminal. While not illustrated in the figure, a second selection terminal of the switch 54₂ is connected with the other selection terminal of the switch 50 corresponding to the different loop coil LCx adjacent to the loop coil LCx₂ on the side opposite to the loop coil LCx₁.

The switch 55 is configured as follows: a common terminal connected with the terminal T₁₂; and one selection terminal is connected with the terminal T₂₁. The other selection terminal of the switch 55 is connected with none. Accordingly, the switch 55 may be constituted by a single-pole single-throw switch.

The switch circuit 30 configured as above performs a function of switching the connection destination of the end T₁₂ (first end) between the inverting input terminal (second input terminal) of the differential amplifier 40₁, the end T₂₁ (second end), the ground terminal, and the non-inverting input terminal (first input terminal) of the differential amplifier 40₁. The sensor controller 31 controls this switching to allow reception of pen signals by using each of the differential method, the single-end method, and the batch input method. This point will be hereinafter discussed in detail.

FIG. 2 illustrates a state of the switch circuit 30 after the sensor controller 31 selected the differential method. The sensor controller 31 in this case connects the other selection terminals of the switches 50 and 51 with the common terminal, and connects the first selection terminals of the switches 53 and 54 with the common terminal. The switches 52 and 55 are in a cutoff state (or a state where the other selection terminal has been selected for each). In this case, both ends of each of the loop coil LCx are connected with the corresponding differential amplifier 40 as indicated by broken lines in FIG. 2. As for the differential amplifier 40₁, for example, the non-inverting input terminal is connected with the end T₁₁ of the loop coil LCx₁, and the inverting input terminal is connected with the end T₁₂ of the loop coil LCx₁. The differential method offers advantageous effects of removal of common mode noise from pen signals received by the respective loop coils LCx, and higher signal intensity of pen signals received by the respective loop coils LCx than in the case of the single-end method described below.

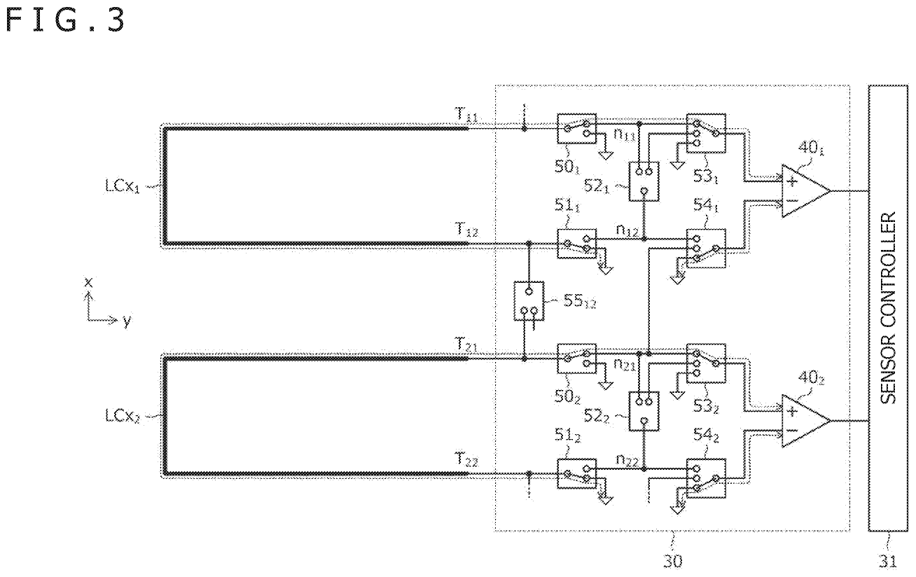

FIG. 3 illustrates a state of the switch circuit 30 after the sensor controller 31 selected the single-end method. The sensor controller 31 in this case connects the other selection terminal of the switch 50 with the common terminal, connects the first selection terminal of the switch 53 with the common terminal, connects the one selection terminal of the switch 51 with the common terminal, and connects the third selection terminal of the switch 54 with the common terminal. Similarly to the case of FIG. 2, the switches 52 and 55 are in a cutoff state (or a state where the other selection terminal has been selected for each). In this case, only the non-inverting input terminal of each of the differential amplifiers 40 is connected with one end of the corresponding loop coil LCx, and the inverting input terminal is in a state connected with the ground terminal as indicated by broken lines in FIG. 3. Meanwhile, the other end of each of the loop coils LCx is in a state connected with the ground terminal. As for the differential amplifier 40₁, for example, the non-inverting input terminal is connected with the end T₁₁ of the loop coil LCx₁, the inverting input terminal is connected with the ground terminal, and the end T₁₂ of the loop coil LCx₁ is connected with the ground terminal. The single-end method offers an advantageous effect of receivability of pen signals by the sensor controller 31 without a necessity of connection between the differential amplifiers 40 with both ends of the loop coils LCx.

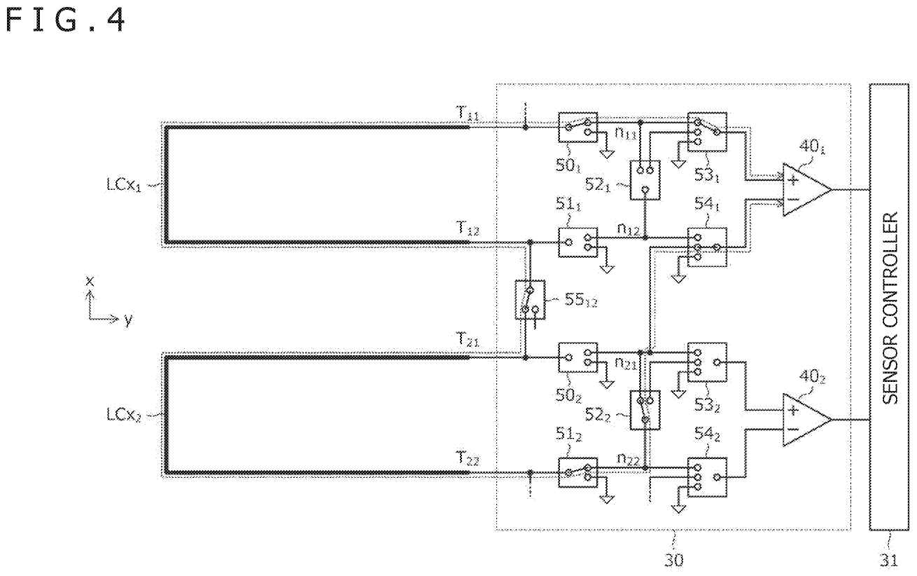

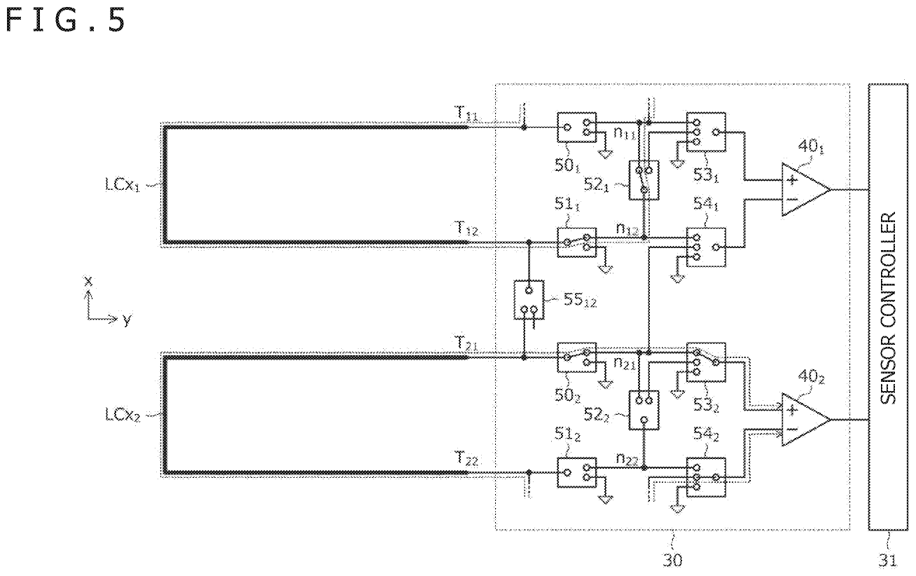

FIGS. 4 and 5 illustrates a state of the switch circuit 30 after the sensor controller 31 selected the batch input method. The sensor controller 31 in this case controls the switch circuit 30 in such a manner as to alternatively produce a first state illustrated in FIG. 4 and a second state illustrated in FIG. 5 in a time-division manner for each of the loop coils LCy.

Initially referring to FIG. 4, the first state is such a state where the two adjoining loop coils LCx are connected in series between the non-inverting terminal and the inverting terminal of each of the differential amplifiers 40. As specifically explained with reference to FIG. 4, for achieving the first state, the sensor controller 31 connects the other selection terminal of each of the switch 50₁ and 51₂ with the common terminal, connects the one selection terminal of each of the switches 52₂ and 55₁₂ with the common terminal, connects the first selection terminal of the switch 53₁ with the common terminal, connects the second selection terminal of the switch 54₁ with the common terminal, and brings the switches 50₂, 51₁, 52₁, 53₂, and 54₂ into a cutoff state. In this manner, the two loop coils LCx₁ and LCx₂ are connected in series between the non-inverting input terminal and the inverting input terminal of the differential amplifier 40₁ as indicated by a broken line in FIG. 4. This applies to the other loop coils LCx not illustrated in the figure.

Subsequently referring to FIG. 5, the second state is a state after one shift from the first state in the x-direction for each of combinations of the two loop coils LCx connected with the corresponding differential amplifier 40 in series. Detailed control performed by the sensor controller 31 for the switch circuit 30 in addition to this shift to achieve the second state is similar to the control for the first state.

The batch input method offers an advantageous effect of higher reception intensity of pen signals according to doubled inductance achieved by connection of the two loop coils LCx in series. However, the first state illustrated in FIG. 4 and the second state illustrated in FIG. 5 need to be produced in a time-series manner. Accordingly, this method requires a twice longer time to receive pen signals than the differential method and the single-end method. As described above, the sensor controller 31 selects the batch input method in cases where a hovering state of the electromagnetic resonance pen 2 is indicated by the writing pressure value contained in the latest pen data already received, and selects the differential method or the single-end method in cases where a pen touch is indicated. In this manner, adaptive switching of the connection method is achievable by using the batch input method to raise reception intensity of pen signals during hovering which is likely to lower reception intensity of pen signals due to a long distance between the coil inside the electromagnetic resonance pen 2 and the touch surface 3a, and using the differential method or the single-end method to reduce the time required for receiving pen signals during pen touch which generates sufficiently high reception intensity.

As described above, according to the position detection system 1 of the present embodiment, the switch groups inside the switch circuit 30 are controlled from the sensor controller 31. In this case, the method for connecting the reception coils of the EMR sensor and the sensor controller 31 is switchable between the differential method, the single-end method, and the batch input method. Accordingly, the sensor controller 31 can detect the pen position and acquire the pen data while making the most of the advantages offered by the respective methods.

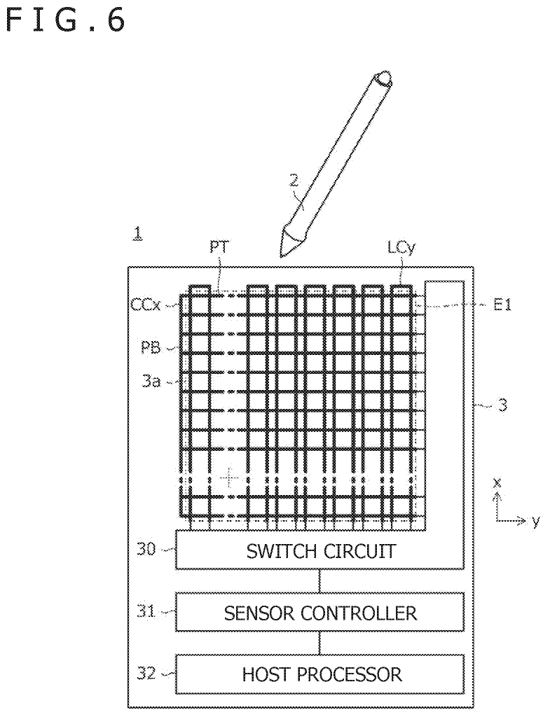

FIG. 6 is a diagram illustrating a configuration of the position detection system 1 according to a second embodiment of the present disclosure. The position detection system 1 according to the present embodiment is different from the position detection system 1 of the first embodiment in that a comb-shaped coil CCx including a base portion PB and a plurality of comb portions PT is adopted as the reception coils of the EMR sensor instead of the plurality of loop coils LCx. Moreover, along with this difference, the internal configuration of the switch circuit 30, and specific control performed by the sensor controller 31 for the switch circuit 30 are also different from those of the position detection system 1 of the first embodiment. In other points, the position detection system 1 of the present embodiment is similar to the position detection system 1 of the first embodiment. Accordingly, the following description will be focused on the differences from the position detection system 1 of the first embodiment.

As illustrated in FIG. 6, the comb-shaped coil CCx is a coil which includes a plurality of the comb portions PT each extending in the y-direction and connected with the base portion PB which is one wire extending in the x-direction. One end of each of the comb portions PT is connected with the base portion PB, while the other end is connected with the switch circuit 30. The other ends of the respective comb portions PT are arranged along a side E1 constituting one side of the touch surface 3a having a rectangular shape.

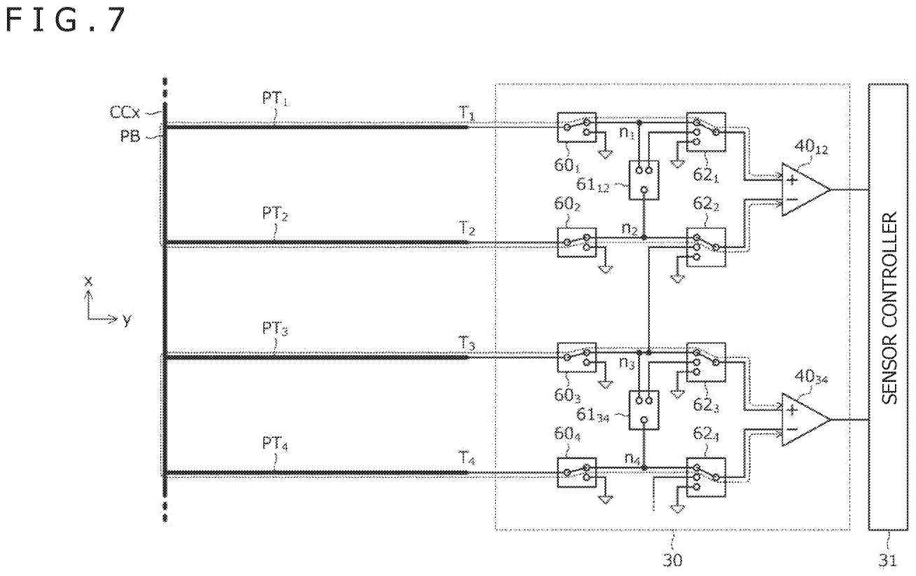

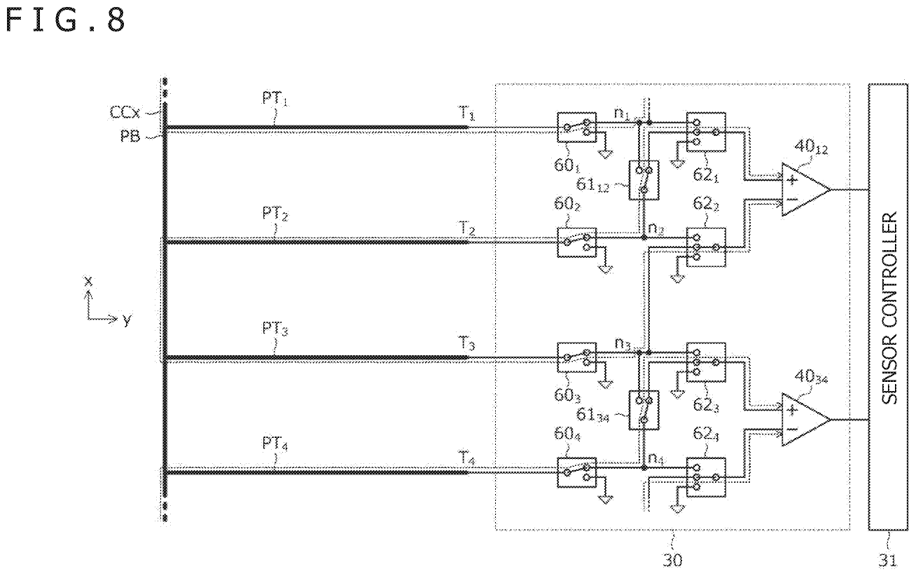

FIGS. 7 and 8 are diagrams illustrating an internal configuration of the switch circuit 30 according to the present embodiment. In the internal configuration of the switch circuit 30, these figures illustrate only a part associated with reception of pen signals by the comb-shaped coil CCx. Described hereinafter in detail with reference to these figures will be a method performed by the sensor controller 31 to receive pen signals with use of the comb-shaped coil CCx.

In addition, needless to say, the comb-shaped coil CCx in actual situations has a larger number of the comb portions PT than the only four loop coils PT1 to PT4 illustrated in FIGS. 7 to 8 for simplifying the explanation. Hereinafter, the other ends of the comb portions PT₁ to PT₄ (the ends opposite to the ends connected with the base portion PB) will be referred to as ends T₁ to T₄, respectively.

Initially referring to FIG. 7, the switch circuit 30 according to the present embodiment includes a plurality of the differential amplifiers 40, and switch groups each including a plurality of switches 60 to 62. The one differential amplifier 40 is provided for each set of the two comb portions PT. The switch 60 is a single-pole double-throw switch, while the switch 62 is a single-pole triple-throw switch. The respective switches 60 and 62 are provided for each of the comb portions PT. In addition, the switch 61 is a single-pole double-throw switch, and is provided for each set of the two comb portions PT. In the following explanation, a subscript “1” will be given to the right side of a symbol of a configuration corresponding to the comb portion PT₁, a subscript “2” will be given to the right side of a symbol of a configuration corresponding to the comb portion PT₂, a subscript “3” will be given to the right side of a symbol of a configuration corresponding to the comb portion PT₃, a subscript “4” will be given to the right side of a symbol of a configuration corresponding to the comb portion PT₄, a subscript “12” will be given to the right side of a symbol of a configuration corresponding to both the com portions PT₁ and PT₂, and a subscript “34” will be given to the right side of a symbol of a configuration corresponding to both the comb portions PT₃ and PT₄, as necessary in some cases to distinguish these configurations from other configurations.

The switch 60₁ is configured as follows: a common terminal is connected with the end T₁; one selection terminal is connected with the ground terminal; and the other selection terminal constitutes a node n₁ illustrated in the figure. The same applies to each of the switches 60₂ to 60₄. The switch 60₂ is configured as follows: a common terminal is connected with the end T₂; one selection terminal is connected with the ground terminal; and the other selection terminal constitutes a node n₂ illustrated in the figure. The switch 60₃ is configured as follows: a common terminal is connected with the end T₃; one selection terminal is connected with the ground terminal; and the other selection terminal constitutes a node n₃ illustrated in the figure. The switch 60₄ is configured as follows: a common terminal is connected with the end T₄; one selection terminal is connected with the ground terminal; and the other selection terminal constitutes a node n₄ illustrated in the figure.

The switch 61₁₂ is configured as follows: a common terminal is connected with the node n2; one selection terminal is connected with the node n₁; and the other selection terminal is connected with a second selection terminal of the switch 62₁. The switch 62₁ is configured as follows: a common terminal is connected with a non-inverting input terminal of the differential amplifier 40₁₂; a first selection terminal is connected with the node n₁; and a third selection terminal is connected with the ground terminal. The switch 62₂ is configured as follows: a common terminal is connected with an inverting input terminal of the differential amplifier 40₁₂; a first selection terminal is connected with the node n₂; a second selection terminal is connected with the node n₃; and a third selection terminal is connected with the ground terminal.

The switch 61₃₄ is configured as follows: a common terminal is connected with the node n₄; one selection terminal is connected with the node n₃; and the other selection terminal is connected with a second selection terminal of the switch 62₃. The switch 62₃ is configured as follows: a common terminal is connected with a non-inverting input terminal of the differential amplifier 40₃₄; a first selection terminal is connected with the node n₃; and a third selection terminal is connected with the ground terminal. The switch 62₄ is configured as follows: a common terminal is connected with an inverting input terminal of the differential amplifier 40₃₄; a first selection terminal is connected with the node n₄; and a third selection terminal is connected with the ground terminal. While not illustrated in the figure, a second selection terminal of the switch 62₄ is connected with the other selection terminal of the switch 60 corresponding to the different comb portion PT adjacent to the comb portion PT₄ on the side opposite to the comb portion PT₃.

The switch circuit 30 configured as above performs a function of switching the connection destination of the end T₂ (first end) between the inverting input terminal (second input terminal) of the differential amplifier 40₁₂, and the non-inverting input terminal (first input terminal) of the differential amplifier 40₁. The sensor controller 31 controls this switching to achieve reception of pen signals while switching between a first state for connecting the end T₂ with the inverting input terminal of the differential amplifier 40₁₂, and a second state for connecting the end T₂ with the non-inverting input terminal of the differential amplifier 40₁₂ in a time-division manner. This point will be hereinafter discussed in detail.

FIG. 7 illustrates the first state of the switch circuit 30. As illustrated in the figure, in the first state, the end T₁ of the comb portion PT₁ is connected with the non-inverting input terminal of the differential amplifier 40₁₂, and the end T₂ of the comb portion PT₂ is connected with the inverting input terminal of the differential amplifier 40₁₂. Meanwhile, the end T₃ of the comb portion PT₃ is connected with the non-inverting input terminal of the differential amplifier 40₃₄, and the end T₄ of the comb portion PT₄ is connected with the inverting input terminal of the differential amplifier 40₃₄. This applies to the other comb portions PT not illustrated in the figure. By these connections, the two adjoining comb portions PT, and a section included in the base portion PB and connecting these comb portions PT constitute one virtual loop coil as indicated by each broken line in FIG. 7. The virtual loop coil thus formed will be hereinafter referred to as a “virtual loop coil.” The respective virtual loop coils are joined with each other via the base portion PB. The studies conducted by the inventor of the present application have revealed that this junction of the virtual loop coils imposes substantially no effect on the characteristics of pen signal reception.

FIG. 8 illustrates the second state of the switch circuit 30. As illustrated in the figure, in the second state, the end T₂ of the comb portion PT₂ is connected with the non-inverting input terminal of the differential amplifier 40₁₂, and the end T₃ of the comb portion PT₃ is connected with the inverting input terminal of the differential amplifier 40₁₂. The end T₁ of the comb portion PT₁, and also the end of the different comb portion PT adjacent to the comb portion PT₁ on the side opposite to the comb portion PT₂, are connected with the different differential amplifier 40 adjacent to the differential amplifier 40₁₂ on the side opposite to the differential amplifier 40₃₄. Similarly, the end T₄ of the comb portion PT₄, and also the end of the different comb portion PT adjacent to the comb portion PT₄ on the side opposite to the comb portion PT₃, are connected with the differential amplifier 40₃₄. This applies to the other comb portions PT not illustrated in the figure. In this case, similarly to the case in FIG. 7, the two adjoining comb portions PT, and a section included in the base portion PB and connecting these comb portions PT constitute one virtual loop coil as indicated by each broken line in FIG. 8. However, combinations of the two comb portions PT constituting each virtual loop coil are shifted in the x-direction from the corresponding combinations in FIG. 7 by the one comb portion PT. The respective virtual loop coils are joined with each other via the base portions PB also in the second state. Similarly to the first state, this junction of the virtual loop coils imposes substantially no effect on the characteristics of pen signal reception.

In cases where pen signals are received only in the first state illustrated in FIG. 7 or the second state illustrated in FIG. 8, wide clearances are produced between the virtual loop coils in the x-direction. In this case, detection accuracy of the pen position in the x-direction lowers. According to the switch circuit 30 of the present embodiment, the sensor controller 31 can receive pen signals in both the first state and the second state in a time-division manner for each of the loop coils LCy. In this case, each clearance between the virtual loop coils can be, on the whole, reduced to no clearance. Accordingly, detection accuracy of the pen position with use of the comb-shaped coil CCx as the reception coils of the EMR sensor is considered to increase.

As described above, according to the position detection system 1 of the present embodiment, pen signals can be received in the first state and the second state in a time-division manner. In this case, each clearance between virtual loop coils can be eliminated to substantially no clearance. Accordingly, detection accuracy of the pen position with use of the comb-shaped coil CCx as the reception coils of the EMR sensor improves.

Note herein that, instead of the one comb portion PT as discussed in the present embodiment by way of example, a plurality of the comb portions PT may be connected with one input terminal of the differential amplifier 40. Two modifications adopting this type of connection will be hereinafter described.

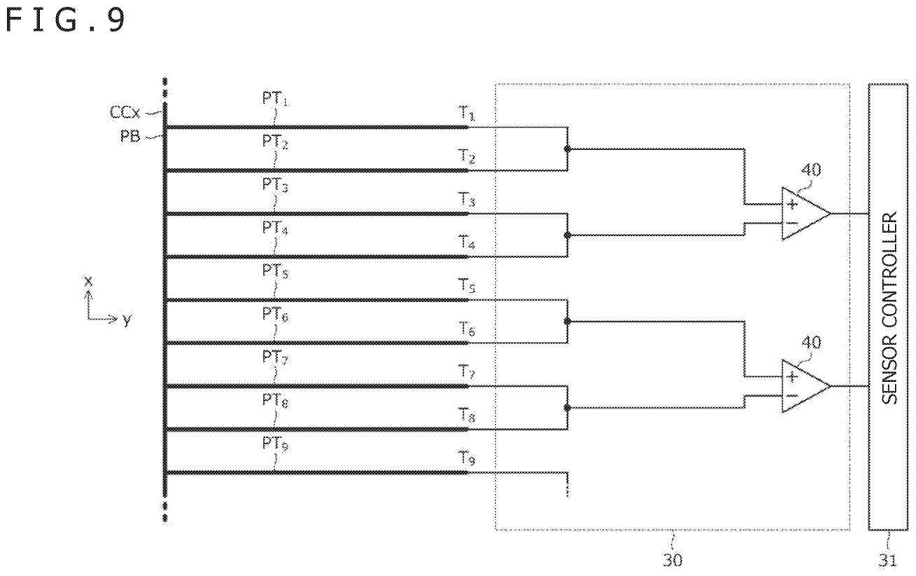

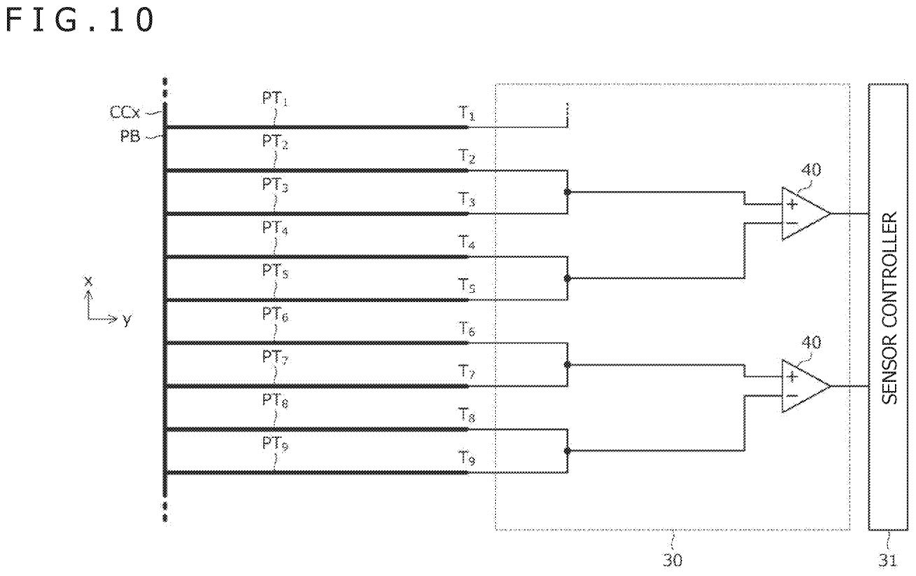

FIGS. 9 and 10 are diagrams illustrating a first state and a second state of the switch circuit 30 according to a first modification of the present embodiment. The present modification is an example which connects the two comb portions PT with one input terminal of the differential amplifier 40. Note that these figures illustrate not the detailed configuration inside the switch circuit 30, but only a connection state between the respective comb portions PT and the differential amplifier 40. The switch circuit 30 according to the present modification has the one differential amplifier 40 for each set of the four comb portions PT.

The sensor controller 31 according to the present modification initially selects the four comb portions PT as one set from the plurality of comb portions PT constituting the comb-shaped coil CCx from the one end side in the x-direction. According to the example in FIG. 9, the comb portions PT₁ to PT₄ constitute one set, and the comb portions PT₅ to PT₈ constitute another set. Thereafter, the sensor controller 31 connects the two comb portions PT, which are included in the four comb portions PT constituting each set and located on the one end side in the x-direction, with a common non-inverting input terminal of the corresponding differential amplifier 40, and connects the other two comb portions PT with a common inverting input terminal of the corresponding differential amplifier 40. In this manner, each set of the four adjoining comb portions PT is connected with the corresponding one differential amplifier 40 to form a state (first state) as illustrated in FIG. 9. In this state, a predetermined number (two in this case) of the ends including the end T₄ (first end) of the comb portion PT₄ are connected with the inverting input terminal of the first differential amplifier 40, and the predetermined number of the ends including the end T₅ (second end) of the comb portion PT₅ are connected with the non-inverting input terminal of the second differential amplifier 40.

Subsequently, the sensor controller 31 shifts the four comb portions PT constituting each set one by one. FIG. 10 illustrates a state after this shift from the state illustrated in FIG. 9. In this case, the comb portions PT₂ to PT₅ constitute one set, and the comb portions PT₆ to PT₇ constitute another set as illustrated in the figure. Thereafter, similarly to the case in FIG. 9, the sensor controller 31 connects the two comb portions PT, which are included in the four comb portions PT constituting each set and located on the one end side in the x-direction, with a common non-inverting input terminal of the corresponding differential amplifier 40, and connects the other two comb portions PT with a common inverting input terminal of the corresponding differential amplifier 40. In this manner, each set of the four adjoining comb portions PT is connected with the corresponding one differential amplifier 40 to form a state (second state) as illustrated in FIG. 10. In this state, the predetermined number of the ends including the end T₄ (first end) of the comb portion PT₄ and the end T₅ (second end) of the comb portion PT₅ are connected with the inverting input terminal of the first differential amplifier 40, and the predetermined number of the ends of the different comb portion PT are connected with the non-inverting input terminal of the second differential amplifier 40.

The sensor controller 31 according to the present modification further carries out three shifts in a similar manner to constitute sets of four types of combination of the four comb portions PT. For each constitution of the sets, the sensor controller 31 performs a process for connecting the two comb portions Pt, which are located on the one end side in the x-direction in the four comb portions PT constituting each set, with a common non-inverting input terminal of the corresponding differential amplifier 40, and for connecting the other two comb portions PT with an inverting input terminal of the corresponding differential amplifier 40. In this manner, the four adjoining comb portions PT are connected to the one differential amplifier 40 in four states including the first state and the second state described above. The sensor controller 31 according to the present modification receives pen signals output from the respective differential amplifiers 40 in each of the four states thus produced. Thereafter, the sensor controller 31 detects the pen position and acquires the pen data on the basis of the received pen signals.

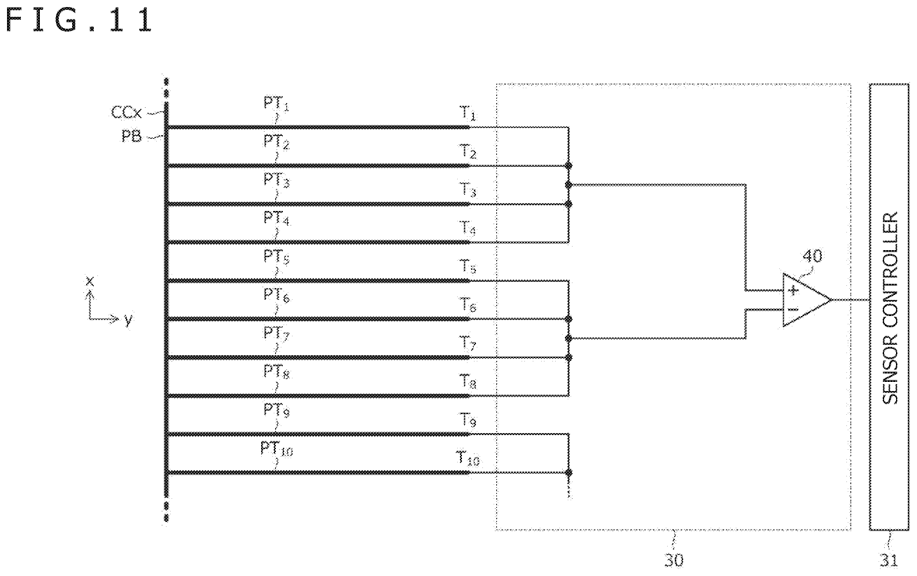

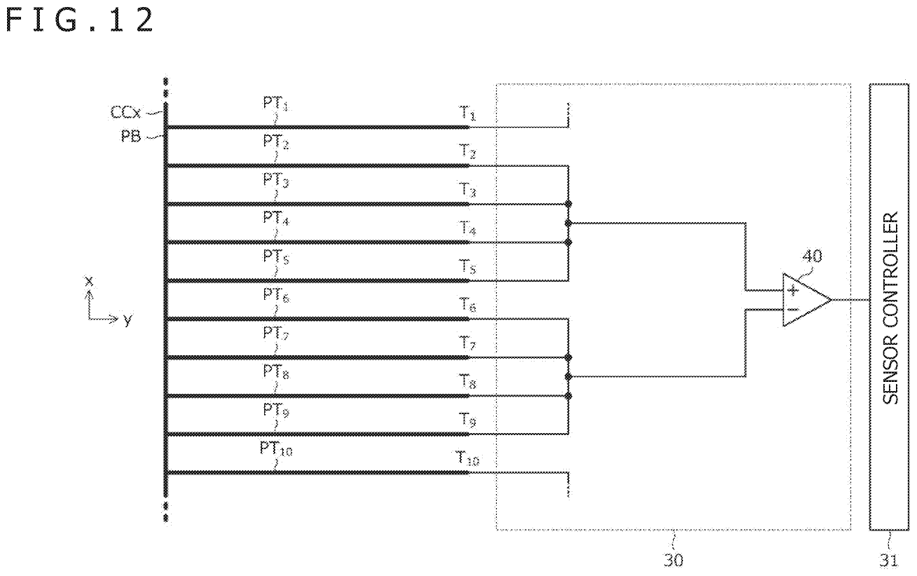

FIGS. 11 and 12 are diagrams illustrating a first state and a second state of the switch circuit 30 according to a second modification of the present embodiment, respectively. The present modification is an example which connects the four comb portions PT with one input terminal of the differential amplifier 40. Similarly to the above modification, these figures illustrate not the detailed configuration inside the switch circuit 30, but only a connection state between the respective comb portions PT and the differential amplifier 40. The switch circuit 30 according to the present modification has the one differential amplifier 40 for each set of the eight comb portions PT.

The sensor controller 31 according to the present modification initially selects the eight comb portions PT for each set from the plurality of comb portions PT constituting the comb-shaped coil CCx from the one end side in the x-direction. According to the example in FIG. 11, the comb portions PT₁ to PT₈ constitute one set. Thereafter, the sensor controller 31 connects the four comb portions PT, which are included in the eight comb portions PT constituting each set and located on the one end side in the x-direction, with a common non-inverting input terminal of the corresponding differential amplifier 40, and connects the other four comb portions PT with an inverting input terminal of the corresponding differential amplifier 40. In this manner, the eight adjoining comb portions PT are connected with the corresponding one differential amplifier 40 to form a state (first state) as illustrated in FIG. 11. In this state, a predetermined number (four in this case) of the ends including the end T₈ (first end) of the comb portion PT₈ are connected with the inverting input terminal of the first differential amplifier 40, and the predetermined number of the ends including the end T₉ (second end) of the comb portion PT₉ are connected with the non-inverting input terminal of the second differential amplifier 40.

Subsequently, the sensor controller 31 shifts the eight comb portions PT constituting each set one by one. FIG. 12 illustrates a state after this shift from the state illustrated in FIG. 11. In this case, the comb portions PT₂ to PT₁₀ constitute one set as illustrated in this figure. Thereafter, similarly to the case in FIG. 11, the sensor controller 31 connects the four comb portions PT, which are included in the eight comb portions PT constituting each set and located on the one end side in the x-direction, with a common non-inverting input terminal of the corresponding differential amplifier 40, and connects the other four comb portions PT with an inverting input terminal of the corresponding differential amplifier 40. In this manner, the eight adjoining comb portions PT are connected with the corresponding one differential amplifier 40 to form a state (second state) as illustrated in FIG. 12. In this state, the predetermined number of the ends including the end T₈ (first end) of the comb portion PT₈ and the end T₉ (second end) of the comb portion PT₉ are connected with the inverting input terminal of the first differential amplifier 40, and the predetermined number of the ends of the different comb portion PT are connected with the non-inverting input terminal of the second differential amplifier 40.

The sensor controller 31 according to the present modification further carries out seven shifts in a similar manner to constitute sets of eight types of combination of the eight comb portions PT. For each constitution of the sets, the sensor controller 31 performs a process for connecting the four comb portions Pt, which are located on the one end side in the x-direction in the eight comb portions PT constituting each set, with a common non-inverting input terminal of the corresponding differential amplifier 40, and for connecting the other four comb portions PT with an inverting input terminal of the corresponding differential amplifier 40. In this manner, the eight adjoining comb portions PT are connected to the one differential amplifier 40 in eight states including the first state and the second state described above. The sensor controller 31 according to the present modification receives pen signals output from the respective differential amplifiers 40 in each of the eight states thus produced. Thereafter, the sensor controller 31 detects the pen position and acquires the pen data on the basis of the received pen signals.

As apparent from the two modifications discussed above, according to the position detection system 1 of the present embodiment, pen signals can be received in a plurality of connection states in a time-division manner even in cases where a plurality of the comb portions PT are connected with the one input terminal of the differential amplifier 40. Accordingly, detection accuracy of the pen position with use of the comb-shaped coil CCx as the reception coils of the EMR sensor improves. Moreover, the connection of a plurality of the comb portions PT with the one input terminal of the differential amplifier 40 in these modifications can produce higher reception intensity of pen signals than the reception intensity in the present embodiment.

Described next will be the position detection system 1 according to a third embodiment of the present disclosure. The position detection system 1 according to the present embodiment is different from the position detection system 1 of the first embodiment in a point of the internal configuration of the switch circuit 30. In other points, the position detection system 1 of the present embodiment is similar to the position detection system 1 of the first embodiment. Accordingly, the following description will be focused on the differences from the position detection system 1 of the first embodiment.

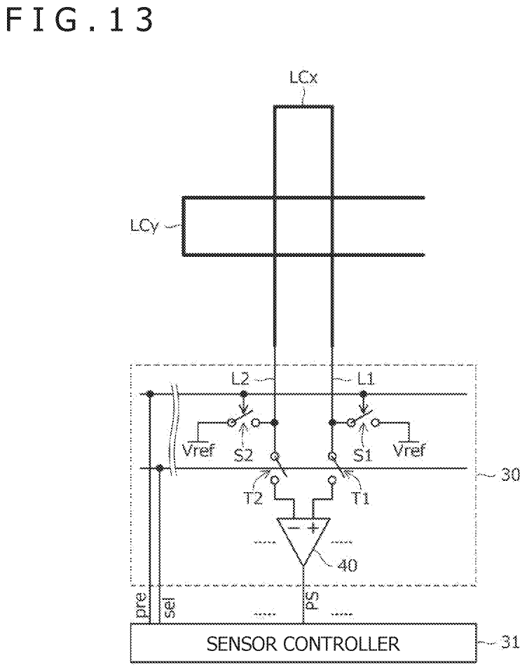

FIG. 13 is a diagram illustrating an internal configuration of the switch circuit 30 according to the present embodiment. This figure illustrates only a configuration associated with the illustrated loop coil LCx. This figure further illustrates the loop coil LCx and LCy one for each, and the sensor controller 31.

As illustrated in FIG. 13, the switch circuit 30 according to the present embodiment includes the differential amplifier 40, wires L1 and L2, and a switch group including switch elements S1, S2, T1, and T2 for each of the loop coils LCx.

The differential amplifier 40 is an amplifier circuit (differential amplifier) which has a non-inverting input terminal, an inverting input terminal, and an output terminal, and is configured to amplify a potential difference between the non-inverting input terminal and the inverting input terminal, and output the amplified potential difference from the output terminal as an output voltage for the ground potential. Output signals of the respective differential amplifiers 40 are supplied to the sensor controller 31 as the pen signals PS.

The wire L1 is a wire which connects one end of the loop coil LCx with a non-inverting input terminal of the corresponding differential amplifier 40. The switch element T1 is a single-pole single-throw switch provided in an intermediate position of the wire L1. In cases where the switch element T1 is turned on, the one end of the loop coil LCx is connected with the non-inverting input terminal of the differential amplifier 40. In cases where the switch element T1 is turned off, the one end of the loop coil LCx is disconnected from the non-inverting input terminal of the differential amplifier 40.

The wire L2 is a wire which connects the other end of the loop coil LCx with an inverting input terminal of the corresponding differential amplifier 40. The switch element T2 is a single-pole single-throw switch provided in an intermediate position of the wire L2. In cases where the switch element T2 is turned on, the other end of the loop coil LCx is connected with the inverting input terminal of the differential amplifier 40. In cases where the switch element T2 is turned off, the other end of the loop coil LCx is disconnected from the inverting input terminal of the differential amplifier 40.

The switch element S1 is a single-pole single-throw switch provided between a power source wire to which a predetermined power source potential Vref (e.g., ground potential or intermediate potential of pen signal) is supplied, and a portion included in the wire L1 and located between the switch element T1 and the loop coil LCx, and performs a function of supplying the power source potential Vref to the one end of the loop coil LCx. Similarly, the switch element S2 is a single-pole single-throw switch provided between a power source wire to which the predetermined power source potential Vref is supplied, and a portion included in the wire L2 and located between the switch element T2 and the loop coil LCx, and performs a function of supplying the power source potential Vref to the other end of the loop coil LCx.

The switch elements S1 and S2 are controlled according to a pre-charge signal pre generated by the sensor controller 31. Meanwhile, the switch elements T1 and T2 are controlled according to a selection signal sel generated by the sensor controller 31. Hereinafter described in detail will be control performed by the sensor controller 31 for the switch elements S1, S2, T1, and T2 on the basis of these signals.

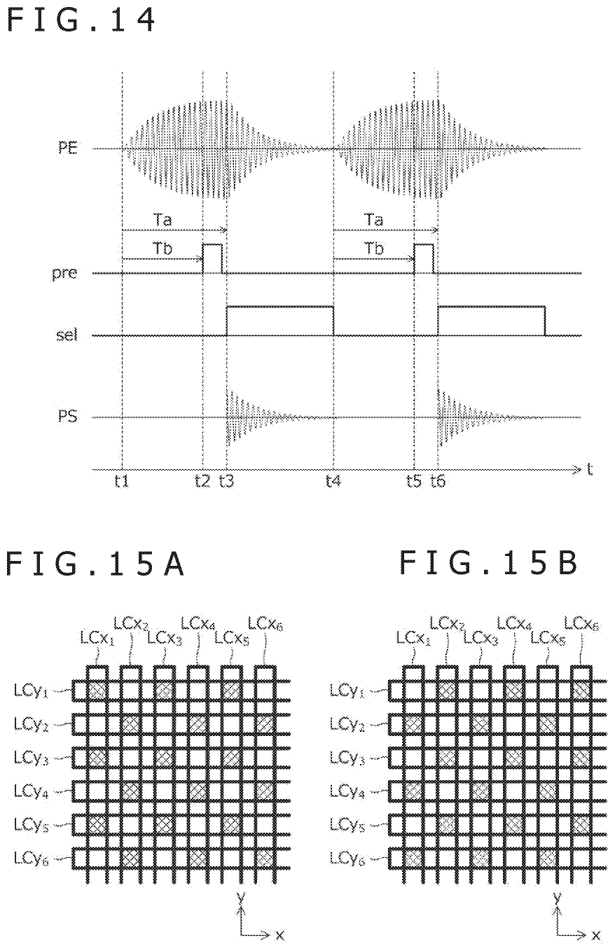

FIG. 14 is a diagram illustrating waveforms of signals and the like associated with control of the switch elements S1, S2, T1, and T2. A voltage PE illustrated in this figure is a voltage between both ends of a coil constituting a resonant circuit of the electromagnetic resonance pen 2. When the sensor controller 31 starts sending of an alternating magnetic field from the loop coil LCy at a time t1, the voltage PE rises in the electromagnetic resonance pen 2 located near the loop coil LCy as illustrated in the figure. The sensor controller 31 continues sending of this alternating magnetic field from the time t1 to a time t3 which is a time after a predetermined period Ta.

The sensor controller 31 activates the pre-charge signal pre at a time t2 which is a time after continuation of sending of the alternating magnetic field (a time after a predetermined period Tb (<Ta) from the time t1). In this manner, the switch elements S1 and S2 illustrated in FIG. 13 are turned on, and supply of the power source potential Vref to the loop coil LCx is started. The sensor controller 31 maintains the pre-charge signal pre in the active state until the time t3 or a time immediately before the time t3, and then returns the pre-charge signal pre to the non-active state. The respective loop coils LCx can be pre-charged by carrying out a series of these processes. Accordingly, an influence of the alternating magnetic fields sent from the loop coils LCy can be eliminated from the loop coils LCx, and the SNR of the pen signals PS can be raised.

Note herein that the switch circuit 30 is configured to supply the power source potential Vref to each of the one end and the other end of the loop coil LCx so as to complete pre-charge in a shorter time as illustrated in FIG. 13. Specifically, with supply of the power source voltage Vref to the loop coil LCx, the potential of the loop coil LCx reaches the power source potential Vref not immediately throughout the loop coil LCx after the supply due to the time constant of the loop coil LCx as described above, but gradually from a region near the power source wire in a certain time. Accordingly, supply of the power source potential Vref to both of the one end and the other end of the loop coil LCx can shorten the time necessary for this change. However, it is not required to equip the configuration for supplying the power source potential Vref to both of the one end and the other end of the loop coil LCx. The power source potential may be supplied to only one of these ends.

Returning to FIG. 14, the sensor controller 31 having stopped sending the alternating magnetic field at the time t3 activates the selection signal sel simultaneously with the sending stop to turn on the switch elements T1 and T2. As a result, an alternating magnetic field sent from the electromagnetic resonance pen 2 generates alternating current in the loop coil LCx, and supplies this current to the sensor controller 31 as the pen signal PS as illustrated in the figure. In this manner, the sensor controller 31 is allowed to acquire the pen position and the pen data on the basis of the pen signal PS. The sensor controller 31 maintains the selection signal sel in the active state until a time t4 at which subsequent sending of the alternating magnetic field starts, and then returns the selection signal sel to the non-active state. After this step, the processes discussed above are repeated.

As described above, the switch circuit 30 and the sensor controller 31 according to the present embodiment can pre-charge the respective loop coils LCx by turning on the switch elements S1 and S2. Accordingly, an influence of alternating magnetic fields sent from the loop coil LCy on the transmission side can be eliminated from the respective loop coils LCx on the reception side, and therefore the SNR of the pen signals PS improves.

FIGS. 15A and 15B are diagrams illustrating a driving method of the EMR sensor according to a modification of the present embodiment. The sensor controller 31 according to the present modification is different from the sensor controller 31 of the present embodiment in that pen signals are received not by all of the plurality of loop coils LCx, but by only half thereof every time an alternating current is supplied to the respective loop coils LCy to perform global scanning described above. The driving method will be hereinafter discussed while focusing on different points. Incidentally, while FIG. 15 illustrates only the loop coils LCx and LCy six for each for simplifying the description, the same applies to cases of the EMR sensor having a larger number of the loop coils LCx and LCy.

FIG. 15A illustrates a first pen signal reception mode, while FIG. 15B illustrates a second pen signal reception mode. The sensor controller 31 according to the present modification detects the pen position by alternating performing the first reception mode and the second reception mode.

It is assumed that the switch circuit 30 according to the present modification is configured to control the switch elements T1 and T2 according to the selection signals sel differently for each of the (2n−1)-th (n is a natural number, an odd number) loop coil LCx from the one end side in the x-direction in the plurality of loop coils LCx, and the 2n-th (even number) loop coil LCx from the one end side in the x-direction in the plurality of loop coils LCx. In this manner, the switch circuit 30 according to the present modification is configured to switch between a first state and a second state according to control from the sensor controller 31. In the first state, the one end and the other end of the (2n−1)-th (odd number) loop coil LCx from the one end side in the x-direction in the plurality of loop coils LCx are connected with the non-inverting input terminal and the inverting input terminal of the corresponding differential amplifier 40, respectively, and the one end and the other end of the 2n-th (even number) loop coil LCx are disconnected from the non-inverting input terminal and the inverting input terminal of the corresponding differential amplifier 40, respectively. In the second state, the one end and the other end of the 2n-th (even number) loop coil LCx from the one end side in the x-direction in the plurality of loop coils LCx are connected with the non-inverting input terminal and the inverting input terminal of the corresponding differential amplifier 40, respectively, and the one end and the other end of the (2n−1)-th (odd number) loop coil LCx are disconnected from the non-inverting input terminal and the inverting input terminal of the corresponding differential amplifier 40.

In the first reception mode illustrated in FIG. 15A, the sensor controller 31 receives pen signals output from the plurality of differential amplifiers 40 by bringing the switch circuit 30 into the first state at the time of supply of alternating current to the (2m−1)-th (m is a natural number, an odd number) loop coil LCy from the one end side in the y-direction in the plurality of loop coils LCy, and into the second state at the time of supply of alternating current to the 2m-th (even number) loop coil LCy from the one end side in the y-direction in the plurality of loop coils LCy. Detection of the pen position around hatched regions illustrated in FIG. 15A is executed by this process.

Meanwhile, in the second reception mode illustrated in FIG. 15B, the sensor controller 31 receives pen signals output from the plurality of differential amplifiers 40 by bringing the switch circuit 30 into the second state at the time of supply of alternating current to the (2m−1)-th (odd number) loop coil LCy from the one end side in the y-direction in the plurality of loop coils LCy, and into the first state at the time of supply of alternating current to the 2m-th (even number) loop coil LCy from the one end side in the y-direction in the plurality of loop coils LCy. Detection of the pen position around hatched regions in FIG. 15B is executed by this process. As apparent from comparison with FIG. 15A, regions not hatched in 15B are hatched in this example.

According to the present modification, more accurate detection of the pen position is achievable than detection of the pen position achieved by supply of alternating current to any of the loop coils LCy in the first state of the switch circuit 30 in the first reception mode, and supply of alternating current to any of the loop coils LCy in the second state of the switch circuit 30 in the second reception mode, for example. As can be understood from FIG. 15A and B, this increase in accuracy is achieved by an effect of such an arrangement where the hatched regions (i.e., the regions from which intensity of pen signals is acquired) are disposed on the upper, lower, left, and right sides of the not hatched regions (i.e., the regions from which intensity of pen signals is not acquired) (in other words, disposed in a grid shape). Accordingly, pen signal intensity distribution can be accurately derived in all directions.

Moreover, according to the present modification, the number of the differential amplifiers 40 simultaneously used is half of that number of the present embodiment. Accordingly, the number of the differential amplifiers 40 prepared inside the switch circuit 30 can be reduced to half. Moreover, for the same reason, the number of circuits disposed inside the sensor controller 31 to receive pen signals can also be reduced to half.

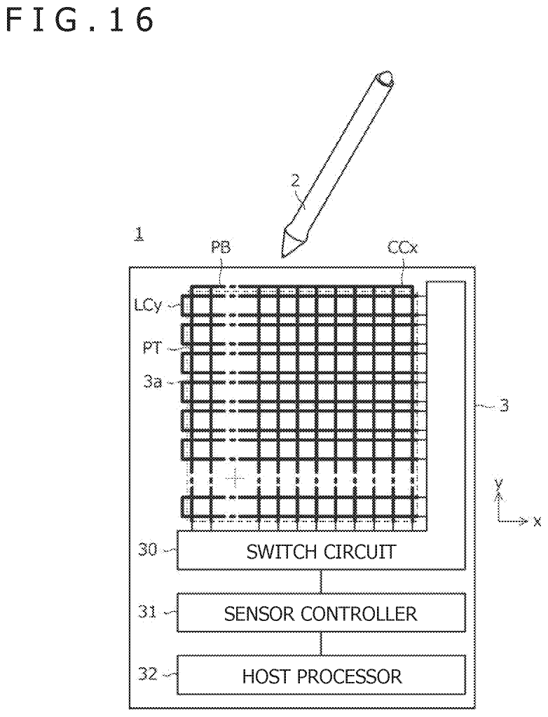

FIG. 16 is a diagram illustrating a configuration of the position detection system 1 according to a fourth embodiment of the present disclosure. The position detection system 1 according to the present embodiment is different from the position detection system 1 of the third embodiment in that the comb-shaped coil CCx including the base portion PB and the plurality of comb portions PT is adopted as the reception coils of the EMR sensor instead of the plurality of loop coils LCx. Moreover, along with this difference, the internal configuration of the switch circuit 30, and specific control performed by the sensor controller 31 for the switch circuit 30 are also different from those of the position detection system 1 of the third embodiment. In other points, the position detection system 1 of the present embodiment is similar to the position detection system 1 of the third embodiment. Accordingly, the following description will be focused on the differences from the position detection system 1 of the third embodiment.

As illustrated in FIG. 16, the comb-shaped coil CCx is a coil which includes a plurality of the comb portions PT each extending in the y-direction, and connected with the base portion PB which is one wire extending in the x-direction. One end of each of the comb portions PT is connected with the base portion PB, while the other end is connected with the switch circuit 30.

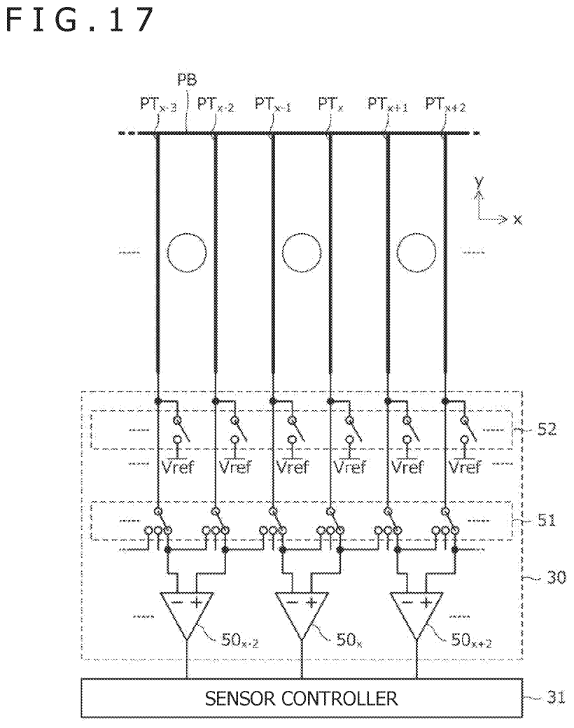

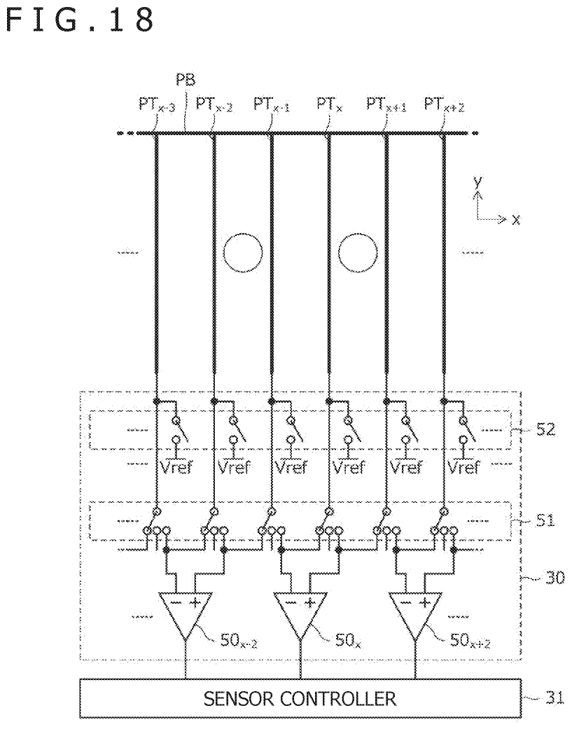

FIGS. 17 and 18 are diagrams illustrating an internal configuration of the switch circuit 30 according to the present embodiment. In the internal configuration of the switch circuit 30, these figures illustrate only a part associated with reception of pen signals by a part of the comb portions PT. In the following description, the x-th comb portion PT from the one end side in the x-direction in the plurality of comb portions PT will be referred to as the comb portion PTₓ for distinction from the other comb portions PT in some cases.

As illustrated in FIGS. 17 and 18, the switch circuit 30 according to the present embodiment includes a plurality of the differential amplifiers 50, and a plurality of the switches 51 and 52. The one differential amplifier 50 is provided for each set of the two comb portions PT, while the switches 51 and 52 are provided for each of the comb portions PT. The configuration and operation of the individual differential amplifiers 50 are similar to those of the differential amplifiers 40 discussed in the third embodiment. In the following description, the differential amplifier 50 provided for the comb portion PTₓ₋₁ and PTₓ in the plurality of differential amplifiers 50 will be referred to as the differential amplifier 50ₓ for distinction from the other differential amplifiers 50 in some cases.

The switches 51 are single-pole triple-throw switches. A common terminal of each of the switches 51 is connected with the other end of the corresponding comb portion PT. The switch 51 which has a common terminal connected with the comb portion PTₓ₋₁ is configured as follows: a first selection terminal is connected with a non-inverting input terminal of the differential amplifier 50ₓ₋₂; a second selection terminal is connected with an open end; and a third selection terminal is connected with an inverting input terminal of the differential amplifier 50ₓ. The switch 51 which has a common terminal connected with the comb portion PTₓ is configured as follows: a first selection terminal is connected with the inverting input terminal of the differential amplifier 50ₓ; a second selection terminal is connected with an open end; and a third selection terminal is connected with a non-inverting input terminal of the differential amplifier 50ₓ.

The switches 52 are single-pole single-throw switches each provided between a power source wire to which power source potential Vref (e.g., ground potential) is supplied, and a wire connecting the common terminal of the corresponding switch 51 with the comb portion PT, and performs a function of supplying the power source potential Vref to the corresponding comb portion PT.

Control for the switches 51 and 52 is executed by the sensor controller 31. In this case, the control performed for the switches 52 is control for pre-charging the comb portions PT, and is executed at timing similar to the control timing of the switches S1 and S2 discussed with reference to FIG. 14. Meanwhile, the control performed for the switches 51 to connect the common terminal with the second selection terminal (open end) is executed at timing similar to the timing for turning off the switches T1 and T2 discussed with reference to FIG. 14. In this manner, each of the differential amplifiers 50 is connected with the comb portion PT only in a period for stopping sending of an alternating magnetic field from the corresponding loop coil LCy.

The control performed by the sensor controller 31 for the switches 51 to connect the common terminal with the first selection terminal or the third connection terminal is executed at such timing that each clearance between virtual loop coils formed inside the comb-shaped coil CCx is reduced to substantially no clearance to accurately detect the pen position even with use of the comb-shaped coil CCx as the reception coils of the EMR sensor. Hereinafter, this point will be specifically discussed.

Initially, the state of the switch circuit 30 will be discussed. The switch circuit 30 is configured to be switchable between a first state and a second state under control by the sensor controller 31. In the first state, each of the switches 51 selects the third selection terminal (a state illustrated in FIG. 17). In the second state, each of the switches 51 selects the first selection terminal (a state illustrated in FIG. 18). In the first state, the other end of the (2n−1)-th (n is a natural number, an odd number) comb portion PT from the one end side in the x-direction in the plurality of comb portions PT, and the other end of the 2n-th (even number) comb portion PT are connected with the inverting input terminal and the non-inverting input terminal of the same differential amplifier 50, respectively, as illustrated in FIG. 17. As a result of this connection, a virtual loop coil is formed by the (2n−1)-th comb portion PT, the 2n-th comb portion PT, and a section included in the base portion PB and connecting these portions PT (each region to which a circle is given in FIG. 17). Meanwhile, in the second state, the other end of the 2n-th (even number) comb portion PT, and the other end of the (2n+1)-th (odd number) comb portion PT from the one end side in the x-direction in the plurality of comb portions PT are connected with the inverting input terminal and the non-inverting input terminal of the same differential amplifier 50, respectively, as illustrated in FIG. 18. As a result of this connection, a virtual loop coil is formed by the 2n-th comb portion PT, the (2n+1)-th comb portion PT, and a section included in the base portion PB and connecting these portions PT (each region to which a circle is given in FIG. 18).

The sensor controller 31 performs, for each of the loop coils LCy, a process for starting supply of alternating current to the corresponding loop coil LCy, stopping this supply, and then switching the state of the switch circuit 30 to the first state to receive pen signals, and further performs a process for again starting supply of alternating current to the same loop coil LCy, stopping this supply, and then switching the state of the switch circuit 30 to the second state to receive pen signals. This process is a common process for global scanning and local scanning. In this manner, each clearance between virtual loop coils formed by the comb-shaped coil CCx can be reduced to substantially no clearance for both global scanning and local scanning. Accordingly, detection accuracy of the pen position achievable with use of the comb-shaped coil CCx as the reception coils of the EMR sensor increases.

According to the switch circuit 30 and the sensor controller 31 of the present embodiment described above, the pen signals can be received in the first state and the second state in a time-division manner, and therefore each clearance between virtual loop coils can be reduced to substantially no clearance. Accordingly, detection accuracy of the pen position achievable with use of the comb-shaped coil CCx as the reception coils of the EMR sensor increases.

Moreover, the switch circuit 30 and the sensor controller 31 according to the present embodiment can pre-charge the respective comb portions PT by turning on the switches 52. Accordingly, similarly to the third embodiment, an influence of alternating magnetic fields sent from the loop coils LCy on the transmission side can be eliminated from the comb portions PT on the reception side, and therefore the SNR of the pen signals PS improves.

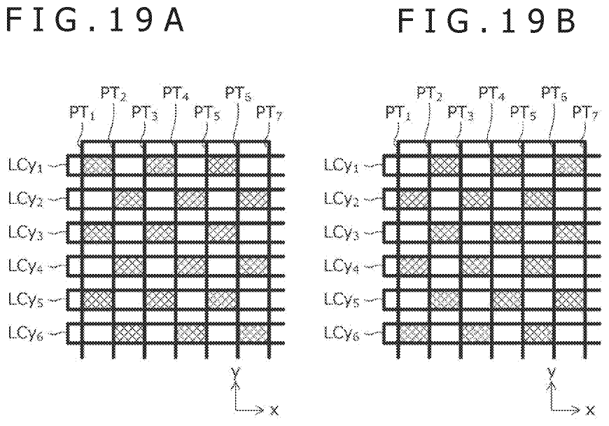

FIGS. 19A and 19B are diagrams illustrating a driving method of the EMR sensor according to a modification of the present embodiment. The sensor controller 31 according to the present modification is different from the sensor controller 31 of the present embodiment in that reception of the pen signals with use of the switch circuit 30 is carried out, for each of the loop coils Lcy, not in both of the first state and the second state, but only in either one of the first and second states to achieve one global scanning. The driving method will be hereinafter discussed while focusing on different points. While only the six loop coils LCy and the seven comb portions PT are illustrated in FIG. 19 for simplifying the description, this method similarly applies to cases where the EMR sensor includes larger numbers of the loop coils LCy and the comb portions PT.

FIG. 19A illustrates a first pen signal reception mode, while FIG. 19B illustrates a second pen signal reception mode. The sensor controller 31 according to the present modification detects the pen position by alternately performing global scanning in the first reception mode and in the second reception mode.

In the first reception mode, the sensor controller 31 receives pen signals output from the plurality of differential amplifiers 50 by bringing the switch circuit 30 into the first state at the time of supply of alternating current to the (2m−1)-th (m is a natural number, an odd number) loop coil LCy from the one end side in the y-direction in the plurality of loop coils LCy, and into the second state at the time of supply of alternating current to the 2m-th (even number) loop coil LCy from the one end side in the y-direction in the plurality of loop coils LCy. Detection of the pen position is executed by this process around hatched regions in FIG. 19A.

Meanwhile, in the second reception mode, the sensor controller 31 receives pen signals output from the plurality of differential amplifiers 50 by bringing the switch circuit 30 into the second state at the time of supply of alternating current to the (2m−1)-th (odd number) loop coil LCy from the one end side in the y-direction in the plurality of loop coils LCy, and into the first state at the time of supply of alternating current to the 2m-th (even number) loop coil LCy from the one end side in the y-direction in the plurality of loop coils LCy. Detection of the pen position is executed by this process around hatched regions in FIG. 19B. As apparent from comparison with FIG. 19A, regions not hatched in FIG. 19A are hatched in this example.

According to the present modification, one global scan can be completed in half of the time required in the present embodiment. Accuracy of the pen position detected by one global scan is lower than that accuracy in the present embodiment. However, the hatched regions in each global scan are disposed in a grid shape similar to the grid shape in the modification of the third embodiment discussed with reference to FIG. 15. Accordingly, more accurate detection of the pen position is achievable than detection of the pen position achieved by supply of alternating current to any of the loop coils LCy in the first state of the switch circuit 30 in the first reception mode and supply of alternating current to any of the loop coils LCy in the second state of the switch circuit 30 in the second reception mode, for example.

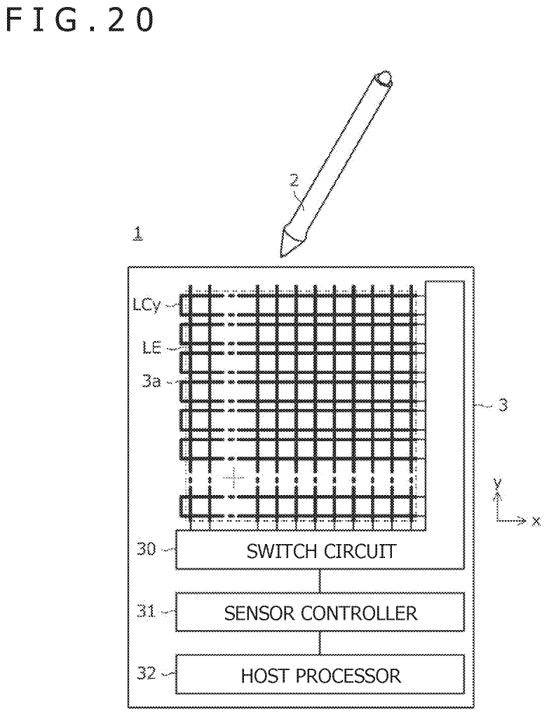

FIG. 20 is a diagram illustrating a configuration of the position detection system 1 according to a fifth embodiment of the present disclosure. The position detection system 1 according to the present embodiment is different from the position detection system 1 of the fourth embodiment in that a plurality of linear electrodes LE each extending in the y-direction and arranged side by side in the x-direction are adopted as the reception coils of the EMR sensor instead of the comb-shaped coil CCx. In other points, the position detection system 1 of the present embodiment is similar to the position detection system 1 of the fourth embodiment. Accordingly, the following description will be focused on the differences from the position detection system 1 of the fourth embodiment.

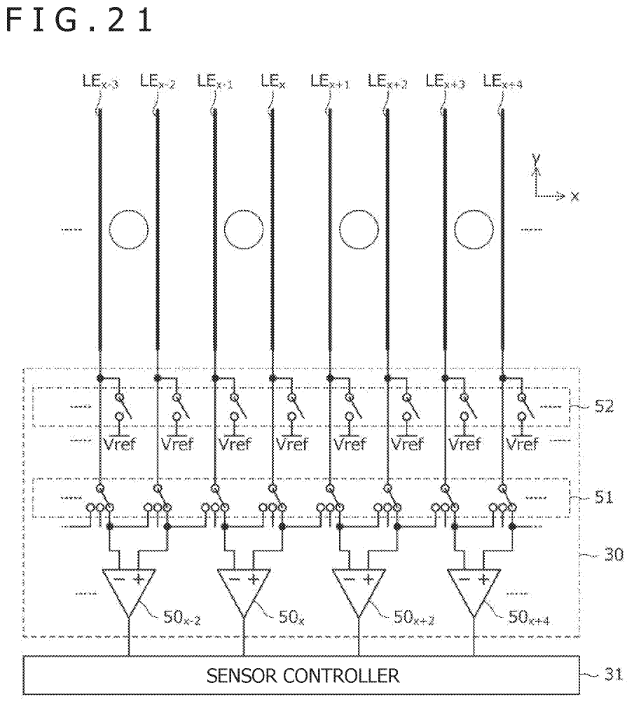

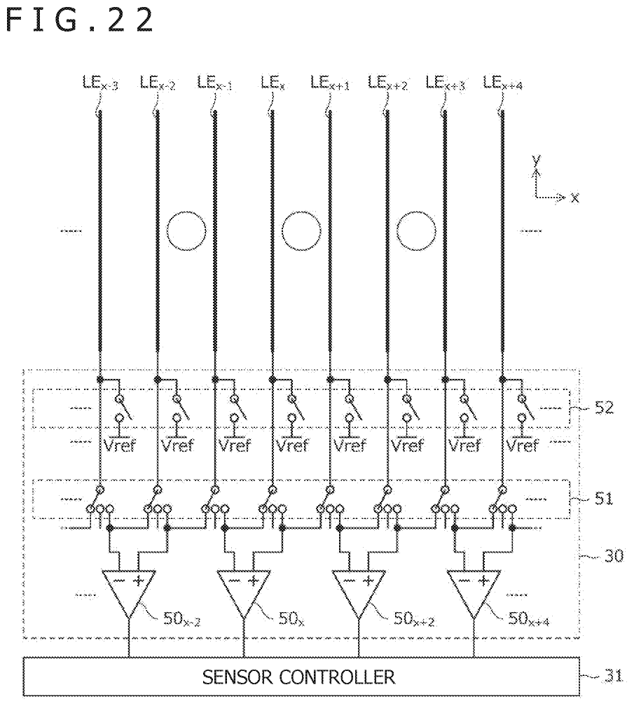

The configuration of the EMR sensor according to the present embodiment is, in short, equivalent to a configuration of the fourth embodiment from which the base portion PB of the comb-shaped coil CCx is removed. FIGS. 21 and 22 are diagrams illustrating an internal configuration of the switch circuit 30 according to the present embodiment. As can be understood from these figures in comparison with FIGS. 17 and 18, the internal configuration of the switch circuit 30 is similar to that configuration of the switch circuit 30 of the fourth embodiment except that the connection destinations are the linear electrodes LE instead of the comb portions PT. Accordingly, similarly to the fourth embodiment, the switch circuit 30 according to the present embodiment is configured to be switchable between the first state and the second state discussed in the fourth embodiment under control by the sensor controller 31. FIG. 21 illustrates the first state, while FIG. 22 illustrates the second state. In addition, the process performed by the sensor controller 31 to receive pen signals under this control may be similar to the corresponding process of the fourth embodiment.

According to the present embodiment, the respective linear electrodes LE are electrically isolated. Accordingly, a virtual loop coil noted in the fourth embodiment is not formed in either the first state or the second state of the switch circuit 30. Bonding between the linear electrodes LE and the coil inside the electromagnetic resonance pen 2 is lower than the bonding of the loop coils LCx discussed in the third embodiment and of the comb-shaped coil CCx discussed in the fourth embodiment. Accordingly, reception intensity of pen signals received by the individual linear electrodes LE is lower than that intensity of the third embodiment and the fourth embodiment. However, the configuration of the switch circuit 30 of the present embodiment can offer such an advantageous effect that high pen signal reception intensity is obtained particularly near the pen position. This effect is achievable by opposite signs of pen signals for the linear electrodes LE on the one side and the linear electrodes LE on the opposite side in the x-direction as viewed from the pen position. Hereinafter, this point will be discussed with reference to a graph of reception intensity.

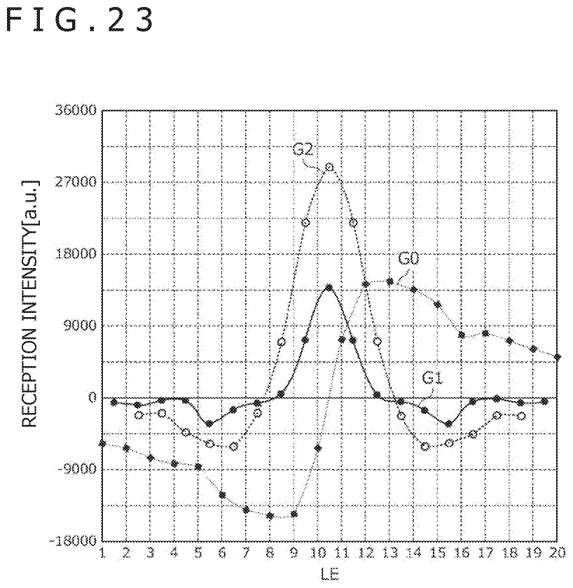

FIG. 23 is a diagram illustrating simulation results of pen signal reception intensity. A graph G1 illustrated in the figure indicates a simulation result of reception intensity of pen signals received by the sensor controller 31 according to the present embodiment. Meanwhile, a graph G0 illustrated in the figure indicates a simulation result of reception intensity of pen signals received by the sensor controller 31 with use of a position detection device of such a type which supplies pen signals received by the respective linear electrodes LE to the sensor controller 31 alone without use of the differential amplifiers 50. The horizontal axis in the figure represents serial numbers of the linear electrodes LE. Each of positions of the points indicated by the graph G1 on the horizontal axis corresponds to an intermediate position of the two linear electrodes LE connected with the same differential amplifier 50 in the x-direction. This applies to a graph G2 discussed below.

FIG. 23 illustrates an example of such a case where the pen tip of the electromagnetic resonance pen 2 is located between the tenth linear electrode LE and the eleventh linear electrode LE. Initially focusing on the graph G0, reception intensity of pen signals received by the linear electrodes LE located at the positions corresponding to the tenth or smaller numbers has signs opposite to signs of that reception intensity of the linear electrodes LE located at the positions corresponding to the eleventh or larger numbers. It is therefore understood that pen signal reception intensity decreases to substantially zero intensity near the pen position.

Subsequently focusing on the graph G1, it is understood that this graph indicates a distribution similar to a regular distribution which has a peak at the pen position. This distribution is obtained because pen signals having opposite signs are mutually boosted by the differential amplifiers 50. It is understood on the basis of these results that the position detection device 3 according to the present embodiment can offer an advantageous effect that high pen signal reception intensity can be obtained near the pen position.

As described above, according to the position detection device 3 of the present embodiment, pen signals having opposite signs are mutually boosted by the differential amplifiers 50. Accordingly, pen signal reception intensity achievable with use of the linear electrodes LE as the Rx coils increases near the pen position.

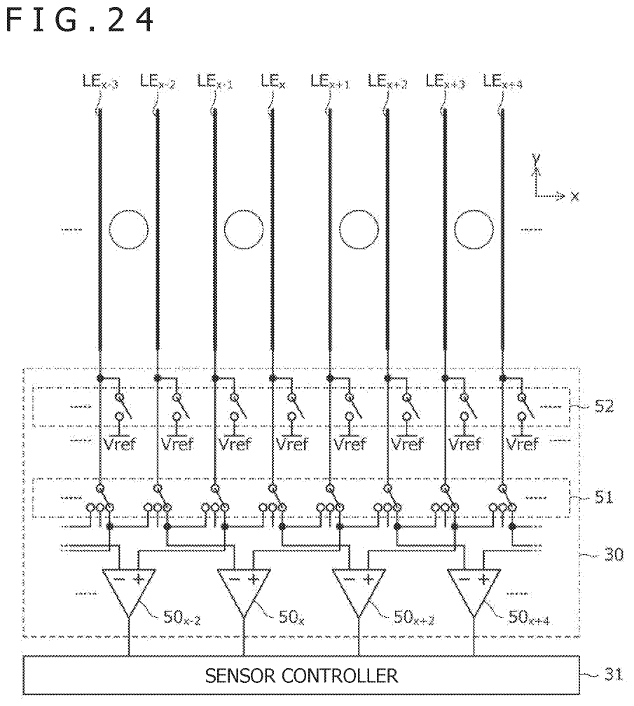

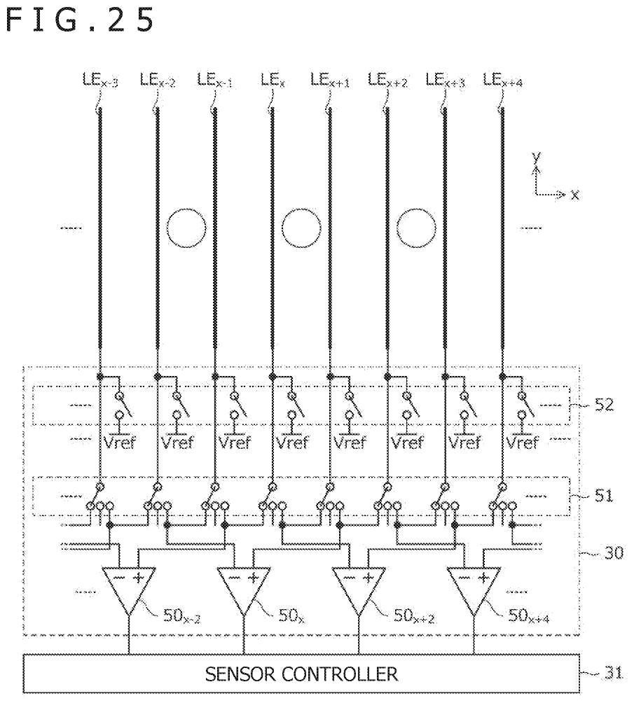

FIGS. 24 and 25 are diagrams illustrating an internal configuration of the switch circuit 30 according to a first modification of the present embodiment. FIG. 24 illustrates the first state, while FIG. 25 illustrates the second state. As can be understood from comparison between FIGS. 24 and 25 and FIGS. 21 and 22, the switch circuit 30 according to the present modification is different from the switch circuit 30 of the present embodiment in that the two linear electrodes LE connected with the same differential amplifier 50ₓ are located not directly adjacent to each other, but adjacent to each other with interposition of the different two linear electrodes LE. The switch circuit 30 of the present modification is similar to the switch circuit 30 of the present embodiment in other points. In addition, specific control performed by the sensor controller 31 for the switch circuit 30 is similar to that control of the present embodiment.

The switch circuit 30 according to the present modification is configured to be switchable between a first state and a second state. In the first state, an end of the (2n−k)-th (k=3, n is a natural number larger than k/2) linear electrode LE and an end of the 2n-th linear electrode LE are connected with the inverting input terminal and the non-inverting input terminal of the same differential amplifier 50, respectively. In the second state, an end of the 2n-th linear electrode LE and an end of the (2n+k)-th linear electrode LE from the one end side in the x-direction in the plurality of linear electrodes LE are connected with the inverting input terminal and the non-inverting input terminal of the same differential amplifier 50, respectively. In the present modification, k=3 is specified. However, when k=1, the switch circuit 30 discussed in the present embodiment is formed. In general, k may be any odd natural number. Accordingly, any value of k which maximizes pen signal reception intensity near the pen position may be selected.

The graph G2 illustrated in FIG. 23 indicates a simulation result of reception intensity of pen signals received by the sensor controller 31 according to the present modification. As can be understood from comparison with the graph G1, according to the switch circuit 30 of the present modification, the obtained distribution has a shape similar to the shape of the regular distribution which has a peak at the pen position similarly to the distribution of the graph G1, and the peak reception intensity is higher than that of the graph G1. Accordingly, the position detection device 3 of the present modification is considered to produce further higher pen signal reception intensity near the pen position with use of the linear electrodes LE as the Rx coils.

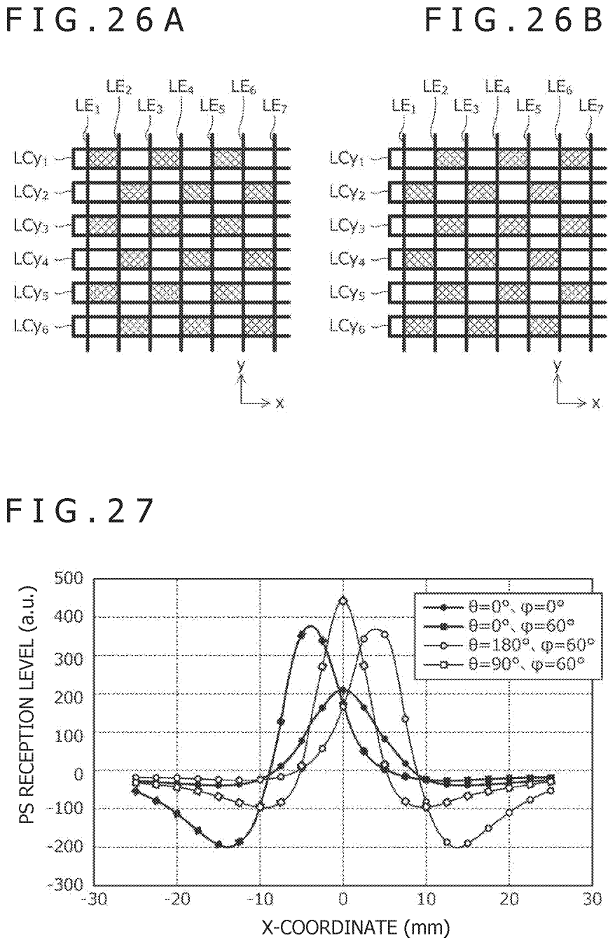

FIGS. 26A and 26B are diagrams illustrating a driving method of the EMR sensor according to a second modification of the present embodiment. The sensor controller 31 according to the present modification is different from the sensor controller 31 of the present embodiment in that reception of pen signals with use of the switch circuit 30 is carried out not in both of the first state and the second state, but only in either one of the first and second states to achieve one global scanning. The driving method will be hereinafter discussed while focusing on different points. While only the six loop coils LCy and the seven linear electrodes LE are illustrated in FIG. 26 for simplifying the description, this method similarly applies to cases where the EMR sensor includes larger numbers of the loop coils LCy and the linear electrodes LE.

FIG. 26A illustrates a first pen signal reception mode, while FIG. 26B illustrates a second pen signal reception mode. The sensor controller 31 according to the present modification detects the pen position by alternately performing global scanning in the first reception mode and in the second reception mode.

In the first reception mode, the sensor controller 31 receives pen signals output from the plurality of differential amplifiers 50 by bringing the switch circuit 30 into the first state at the time of supply of alternating current to the (2m−1)-th (m is a natural number, an odd number) loop coil LCy from the one end side in the y-direction in the plurality of loop coils LCy, and into the second state at the time of supply of alternating current to the 2m-th (even number) loop coil LCy from the one end side in the y-direction in the plurality of loop coils LCy. Detection of the pen position is executed by this process around hatched regions in FIG. 26A.

Meanwhile, in the second reception mode, the sensor controller 31 receives pen signals output from the plurality of differential amplifiers 50 by bringing the switch circuit 30 into the second state at the time of supply of alternating current to the (2m−1)-th (odd number) loop coil LCy from the one end side in the y-direction in the plurality of loop coils LCy, and into the first state at the time of supply of alternating current to the 2m-th (even number) loop coil LCy from the one end side in the y-direction in the plurality of loop coils LCy. Detection of the pen position is executed by this process around hatched regions in FIG. 26B. As apparent from comparison with FIG. 26A, regions not hatched in FIG. 26A are hatched in this example.

According to the present modification, one global scan can be completed in half of the time required in the present embodiment. Accuracy of the pen position detected by one global scan is lower than that accuracy in the present embodiment. However, the hatched regions in each global scan are disposed in a grid shape similar to the grid shape in the modification of the third embodiment discussed with reference to FIG. 15. Accordingly, more accurate detection of the pen position is achievable than detection of the pen position achieved by supply of alternating current to any of the loop coils LCy in the first state of the switch circuit 30 in the first reception mode, and supply of alternating current to any of the loop coils LCy in the second state of the switch circuit 30 in the second reception mode, for example.

Described next will be the position detection system 1 according to a sixth embodiment of the present disclosure. The position detection system 1 according to the present embodiment is different from the third embodiment in a point of the internal configuration of the sensor controller 31. In other points, the position detection system 1 of the present embodiment is similar to the position detection system 1 of the first embodiment. Accordingly, the following description will be focused on the differences from the position detection system 1 of the third embodiment.

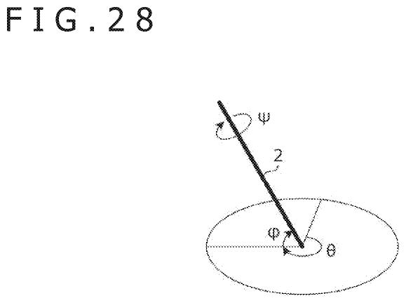

FIG. 27 is a diagram illustrating reception of pen signals with use of the position detection system 1 according to the third embodiment. Meanwhile, FIG. 28 is a diagram for explaining an azimuth angle θ and a tilt angle Φ used in FIG. 27. Before discussing the position detection system 1 according to the present embodiment, the position detection system 1 according to the present embodiment will be hereinafter touched upon with reference to these figures.

As illustrated in FIG. 28, three angles of the azimuth angle θ, the tilt angle Φ, and a rotation angle φ are defined for the electromagnetic resonance pen 2. The azimuth angle θ is an angle which represents a direction indicated by the pen tip of the electromagnetic resonance pen 2 in contact with the touch surface 3a, and is expressed by an angle formed by a predetermined axis set inside the touch surface 3a, and projection of the pen axis of the electromagnetic resonance pen 2 to the touch surface 3a. The tilt angle Φ is an angle which represents a tilt of the electromagnetic resonance pen 2 with respect to the touch surface 3a, and is expressed by an angle formed by the pen axis of the electromagnetic resonance pen 2 and the touch surface 3a. The rotation angle φ is an angle which represents a rotation amount of the electromagnetic resonance pen 2 itself around the pen axis. The problems solved by the position detection system 1 according to the present embodiment are associated with the azimuth angle θ and the tilt angle Φ in the foregoing angles.

FIG. 27 illustrates reception levels of the pen signals PS received by the loop coils LCx corresponding to respective x-coordinates when the azimuth angles θ and the tilt angles Φ are (θ, Φ)=(0°, 0°) (0°, 60°) (180°, 60°) (90°, 60°), for the electromagnetic resonance pen 2 whose pen tip is located at the x-coordinate of 0 mm. As illustrated in the figure, the reception level of the pen signal PS has a peak at the position of the x-coordinate of 0 mm in each of the cases of (θ, Φ)=(0°, 0°) (90°, 60°). However, the peak position of the reception level of the pen signal PS is shifted to the minus side in the case of (θ, Φ)=(0−, 60°). Moreover, the peak position of the reception level of the pen signal PS is shifted to the plus side in the case of (θ, Φ)=(180°, 60°). As apparent from the above, according to the position detection system 1 of the third embodiment, the peak position of the reception level of the pen signal PS may be shifted from the original pen tip depending on the combination of the azimuth angle θ and the tilt angle Φ of the electromagnetic resonance pen 2. The position detection system 1 according to the present embodiment is designed to reduce deterioration of detection accuracy of the pen position caused by these shifts.

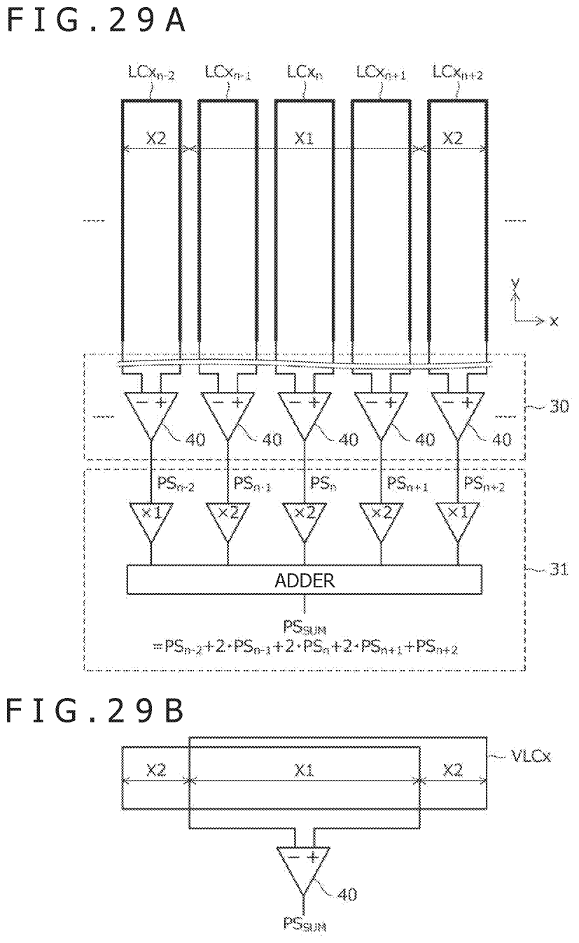

FIG. 29A is a diagram for explaining a process performed by the sensor controller 31 according to the present embodiment. As illustrated in the figure, the sensor controller 31 of the present embodiment is configured to calculate a sum of the pen signal PSₙ received by the n-th loop coil LCxₙ and the pen signal PS received by the one or more loop coils LCx located near the loop coil LCxₙ with different weights, and derive the position of the electromagnetic resonance pen 2 on the basis of a summed pen signal PSₛᵤₘ obtained by this summation.

Specifically, the sensor controller 31 according to the present embodiment carries out the summation of the pen signals PSₙ₋₂ to PSₙ₊₂ received by the five loop coils LCx constituted by the (n−2)-th loop coil LCxₙ₋₂ to (n+2)-th loop coil LCxₙ₊₂ such that the weights of the pen signals PSₙ₋₁ to PSₙ₊₁ received by the three loop coils LCx located at the center in the five loop coils LCx becomes twice larger than the weights of the pen signals ₙ₋₂ and PSₙ₊₂ received by the other two loop coils LCx. In this case, PS_{SUM}=PSₙ₋₂+2 PSₙ₋₁+2 PSₙ+2 PSₙ₊₁+PSₙ₊₂ holds as illustrated in the figure.

FIG. 29B is a diagram illustrating a virtual loop coil VLCx obtained by the summation indicated in FIG. 29A. As illustrated in this figure, the summed pen signal PS_{SUM} obtained by the summation illustrated in FIG. 29A is a signal equivalent to the pen signal PS received by a duplex winding coil which has an internal wire having a width of X1 (a width corresponding to the three loop coils LCx), and an external wire located at a distance of X2 (a width of the one loop coil LCx) from the internal wire.

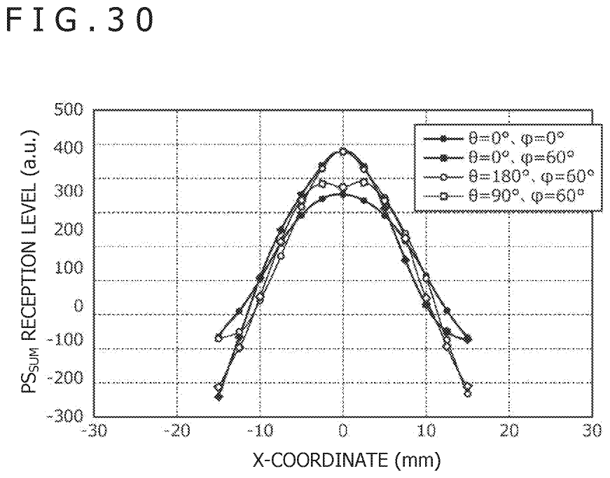

FIG. 30 is a diagram illustrating reception levels of the summed pen signal PS_{SUM} in a case where the pen tip of the electromagnetic resonance pen 2 is located at the position of the x-coordinate of 0 mm. Similarly to FIG. 27, this figure illustrates the reception levels of the summed pen signals PS_{SUM} obtained by the loop coils LCx corresponding to respective x-coordinates when the azimuth angle θ and the tilt angle Φ are (θ, Φ)=(0°, 0°) (0°, 60°) (180°, 60°) (90°, 60°), respectively (signals obtained by weighted-summation of the pen signals PS received by the five loop coils LCx around the corresponding loop coils LCx).

As illustrated in FIG. 30, the peak position of the reception level of the summed pen signal PS_{SUM} is located at the position of the x-coordinate of 0 mm regardless of the values of the azimuth angle θ and the tilt angle Φ of the electromagnetic resonance pen 2. When (θ, Φ) =(90°, 60°), the reception level of the summed pen signal PS_{SUM} slightly drops at the position of the x-coordinate of 0 mm. However, because of the symmetrical shape of the reception level, detection accuracy of the pen position is not lowered by this drop. Accordingly, the position detection system 1 of the present embodiment is considered to achieve accurate detection of the pen position even if the electromagnetic resonance pen 2 is tilted with respect to the touch surface 3a.

As described above, the position detection system 1 according to the present embodiment derives the position of the electromagnetic resonance pen 2 on the basis of the summed pen signal PS_{SUM} calculated by summing the pen signals PS received by a plurality of the loop coils LCx with different weights. Accordingly, accurate detection of the position of the electromagnetic resonance pen 2 is achievable even if the electromagnetic resonance pen 2 is tilted with respect to the touch surface 3a.

Described next will be the position detection system 1 according to a seventh embodiment of the present disclosure. The position detection system 1 according to the present embodiment is different from the fourth embodiment in that the position detection device 3 is a smartphone including a built-in foldable display, and in points of the internal configuration of the switch circuit 30 and the internal processing performed by the sensor controller 31. In other points, the position detection system 1 of the present embodiment is similar to the position detection system 1 of the fourth embodiment. Accordingly, the following description will be focused on the differences from the position detection system 1 of the fourth embodiment.

Note herein that the method performed by the switch circuit 30 and the sensor controller 31 for detecting a position of the electromagnetic resonance pen 2 according to the fourth embodiment will be referred to as an “ODD/EVEN method” in some cases in the following description. In this case, “ODD” and “EVEN” correspond to the first state and the second state, respectively, of the switch circuit 30 discussed in the fourth embodiment. Meanwhile, a method performed by the switch circuit 30 and the sensor controller 31 for detecting a position of the electromagnetic resonance pen 2 according to the present embodiment will be referred to as an “A/B/C method” in some cases. As will be described below in detail, the switch circuit 30 according to the present embodiment is configured to be switchable between three states of first to third states. In this case, “A,” “B,” and “C” correspond to the first state, the second state, and the third state, respectively.

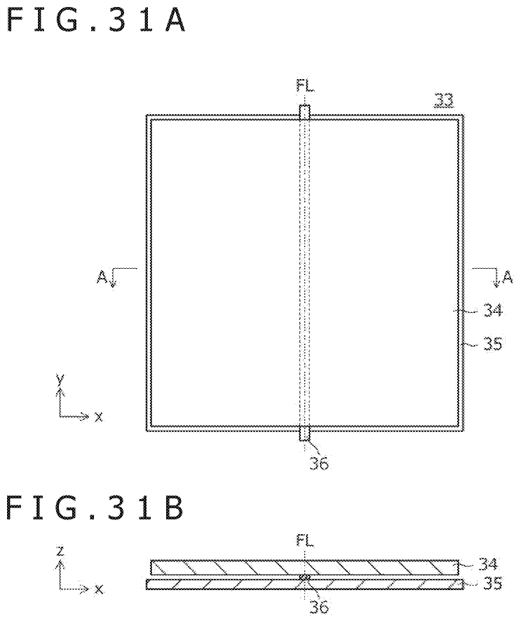

FIG. 31A is a plan view of an EMR sensor 33 included in the position detection device 3 according to the present embodiment, while FIG. 31B is a cross-sectional view of the EMR sensor 33 taken along a line A to A indicated in FIG. 31A. As illustrated in these figures, the EMR sensor 33 includes a substrate 34 where reception coils and transmission coils are formed, and a magnetic sheet 35 made from magnetic material. The magnetic sheet 35 is a component which functions as magnetic paths for magnetic fields generated in the coils inside the substrate 34, and is so arranged as to cover the entire area of one surface (the surface opposite to the touch surface 3a) of the substrate 34.

Needless to say, in cases where a display (not illustrated) included in the position detection device 3 is a foldable display, the EMR sensor 33 is also required to be foldable. A component 36 illustrated in the figure is a conductive hinge component needed for this purpose, and is disposed between the substrate 34 and the magnetic sheet 35 along a folding line FL.

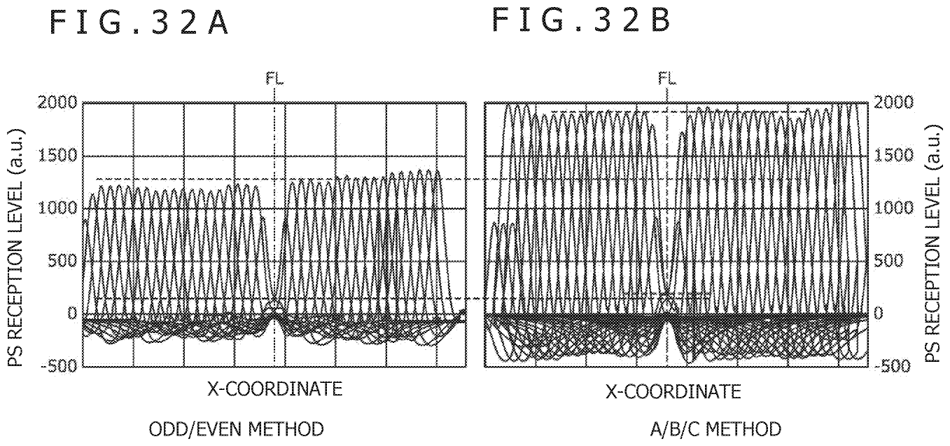

FIG. 32A is a diagram collectively illustrating distributions of reception levels of the pen signals PS received in cases where the pen tip of the electromagnetic resonance pen 2 is located at respective positions in the x-direction on an assumption that the position detection device 3 according to the present embodiment adopts the ODD/EVEN method. According to the ODD/EVEN method, the reception levels of the pen signal PS considerably drop near the folding line FL as illustrated in the figure. This drop results from magnetic field disturbances caused by the hinge component 36 illustrated in FIGS. 31A and 31B. It is difficult to derive the pen position near the folding line FL from the reception levels illustrated in FIG. 32A. Accordingly, improvement of the reception levels of the pen signals PS near the folding line FL has been demanded. The position detection system 1 according to the present embodiment is designed to achieve improvement of the reception levels of the pen signals PS as demanded by using the A/B/C method instead of the ODD/EVEN method.

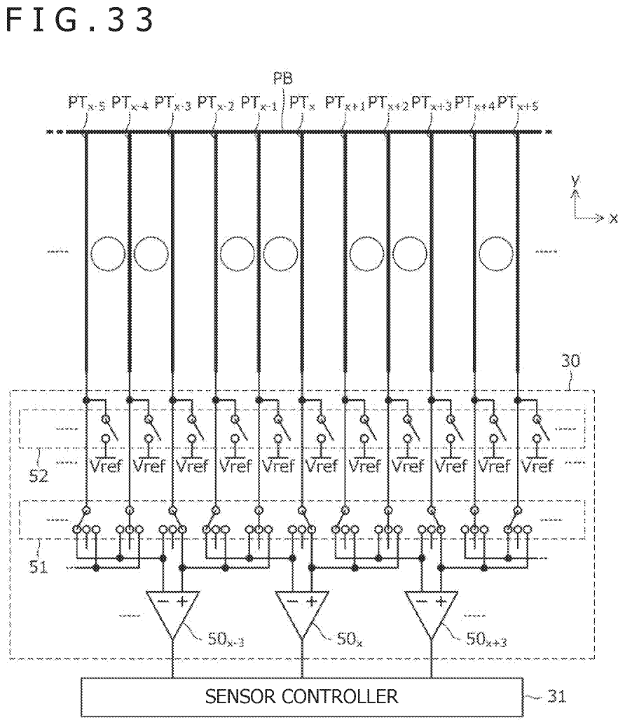

FIGS. 33 to 35 are diagrams illustrating an internal configuration of the switch circuit 30 according to the present embodiment. Similarly to FIGS. 17 and 18, these figures illustrate only an area associated with reception of pen signals by part of the comb portions PT included in the internal configuration of the switch circuit 30. In the following description, the x-th comb portion PT from the one end side in the x-direction in the plurality of comb portions PT will be referred to as the comb portion PTₓ for distinction from the other comb portions PT in some cases.

As illustrated in FIGS. 33 to 35, the switch circuit 30 according to the present modification has one differential amplifier 50 for each set of the three comb portions PT. In the following description, the differential amplifier 50 corresponding to the comb portion PTₓ₋₁, PTₓ, and PTₓ₊₁ in the plurality of differential amplifiers 50 will be referred to as the differential amplifier 50ₓ for distinction from the other differential amplifiers 50 in some cases.

A common terminal of each of the switches 51 according to the present embodiment is connected with the other end of the corresponding comb portion PT. The switch 51 which has a common terminal connected with the comb portion PTₓ is connected as follows: a first selection terminal is connected with an inverting input terminal of the differential amplifier 50ₓ; a second selection terminal is connected with an open end; and a third selection terminal is connected with a non-inverting input terminal of the differential amplifier 50ₓ. The switch 51 which has a common terminal connected with the comb portion PTₓ₋₁ is connected as follows: a first selection terminal is connected with the inverting input terminal of the differential amplifier 50ₓ; a second selection terminal is connected with an open end; and a third selection terminal is connected with a non-inverting input terminal of the differential amplifier 50ₓ₋₂. The switch 51 which has a common terminal connected with the comb portion PTₓ₊₁ is connected as follows: a first selection terminal is connected with an inverting input terminal of the differential amplifier 50ₓ₊₂; a second selection terminal is connected with an open end; and a third selection terminal is connected with the non-inverting input terminal of the differential amplifier 50ₓ. Summarizing the foregoing configurations on the differential amplifier 50ₓ side, the respective first selection terminals of the three switches 51 corresponding to the comb portions PTₓ₋₂, PTₓ₋₁, and PTₓ are connected with the inverting input terminal of the common differential amplifier 50x, while the respective third selection terminals of the three switches 51 corresponding to the comb portions PTₓ, PTₓ₊₁, and PTₓ₊₂ are connected with the non-inverting input terminal of the common differential amplifier 50ₓ.

The switch circuit 30 according to the present embodiment functions as a selection circuit which selects two from the five corresponding comb portions PT for each of the differential amplifiers 50 (for the differential amplifier 50ₓ, the comb portions PTₓ₋₂, PTₓ₋₁, PTₓ, PTₓ₊₁, and PTₓ₊₂) according to control by the sensor controller 31, and connects the selected two comb portions PT with the differential amplifier 50 functioning as the reception circuit.

Concerning the differential amplifier 50ₓ discussed herein, for example, the sensor controller 31 according to the present embodiment controls the switch circuit 30 such that a first state for selecting the comb portion PTₓ₋₂ and PTₓ, a second state for selecting the comb portions PTₓ₋₁ and PTₓ₊₁, and a third state for selecting the comb portions PTₓ and PTₓ₊₂ sequentially appear. In other words, the sensor controller 31 according to the present embodiment performs a function of achieving the A/B/C method described above. After completion of the control of the plurality of switches 51 for producing the third state, the sensor controller 31 repeats the same control from the first state. The same applies to the different differential amplifier 50. The sensor controller 31 controls the switch circuit 30 such that the respective switches 51 corresponding to the differential amplifier 50ₓ and the respective switches 51 corresponding to the different differential amplifier 50 synchronously come into the same state.

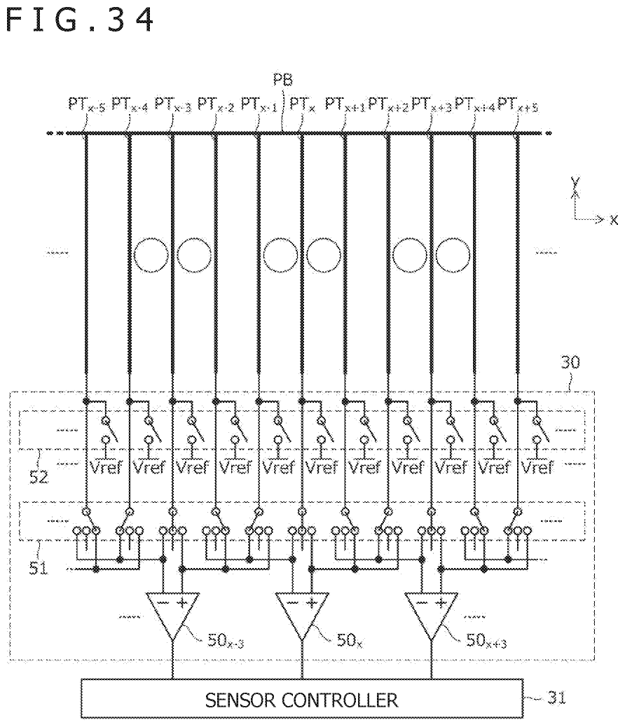

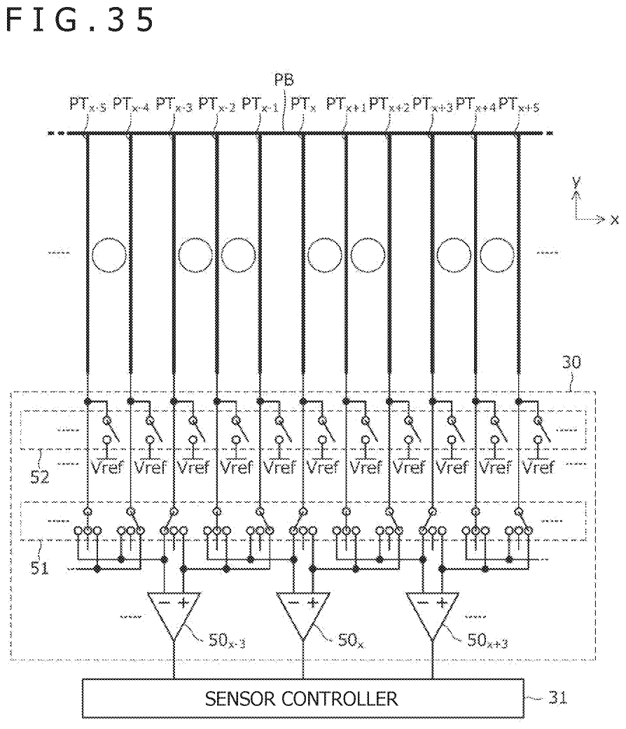

FIGS. 33 to 35 are diagrams illustrating the first state, the second state, and the third state of the switch circuit 30, respectively. In the first state illustrated in FIG. 33, the comb portions PTₓ₋₂ and PTₓ are connected with the respective input terminals of the differential amplifier 50ₓ. The comb portions PTₓ₋₂ and PTₓ thus connected, and a section included in the base portion PB and connecting these comb portions constitute one virtual loop coil. This applies to the other differential amplifiers 50. Similarly, in the second state illustrated in FIG. 34, the comb portions PTₓ₋₁ and PTₓ₊₁ are connected with the respective input terminals of the differential amplifier 50ₓ. The comb portions PTₓ₋₁ and PTₓ₊₁ thus connected, and a section included in the base portion PB and connecting these comb portions constitute one virtual loop coil. Moreover, in the third state illustrated in FIG. 35, the comb portions PTₓ and PTₓ₊₂ are connected with the respective input terminals of the differential amplifier 50ₓ. The comb portions PTₓ and PTₓ₊₂ thus connected, and a section included in the base portion PB and connecting these comb portions constitute one virtual loop coil.

As can be understood from the above, according to the A/B/C method, the virtual loop coil shifts in the x-direction by a distance (second distance) shorter than a distance (first distance) between the two comb portions PT constituting the virtual loop coil. The first distance is a distance between the two comb portions PT adjacent to each other with interposition of the one comb portion PT, while the second distance is a distance between the two comb portions PT without interposition of the different comb portions PT.

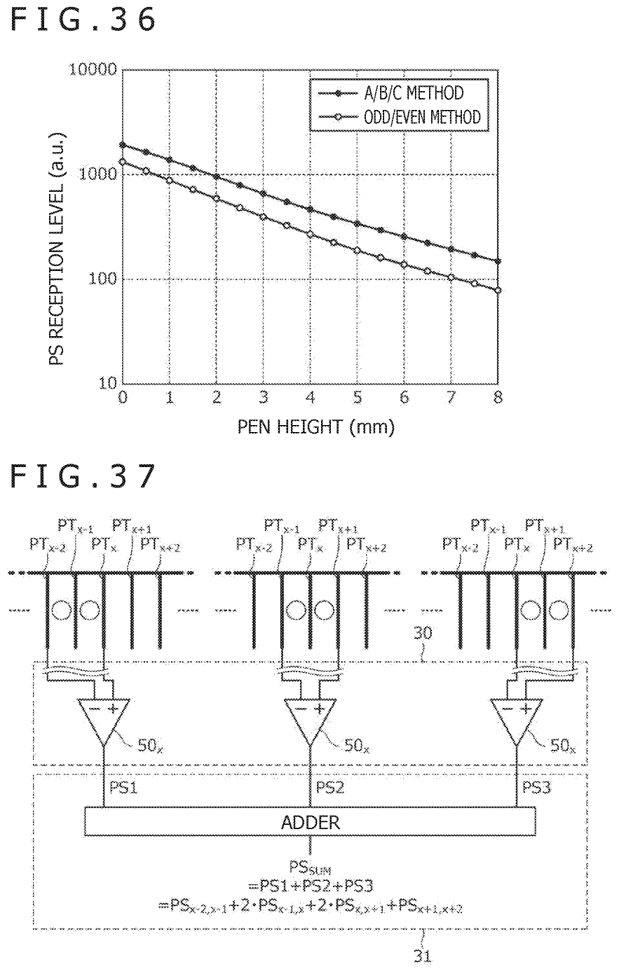

FIG. 36 is a diagram plotting maximum values of the reception levels of the pen signals PS obtained by the ODD/EVE method, and maximum values of the reception levels of the pen signals PS obtained by the A/B/C method, for each distance (pen height) between the pen tip of the electromagnetic resonance pen 2 and the touch surface 3a. It is understood from the results in this figure that the reception levels of the pen signals PS obtained by the A/B/C method are higher than by the ODD/EVEN method at any pen heights.

FIG. 32B is a diagram collectively illustrating distributions of reception levels of the pen signals PS received in the position detection device 3 of the present embodiment (i.e., the position detection device 3 adopting the A/B/C method) in cases where the pen tip of the electromagnetic resonance pen 2 is located at respective positions in the x-direction. As apparent from comparison with FIG. 32A, the reception levels of the pen signals PS are higher in the case of adoption of the A/B/C method than in the case of adoption of the ODD/EVEN method for both of positions near the folding line FL and positions away from the folding line FL. Accordingly, the position detection system 1 of the present embodiment is considered to improve the reception levels of the pen signals PS near the folding line FL.

As described above, the position detection system 1 according to the present embodiment adopts, as the method for detecting the position of the electromagnetic resonance pen 2, the A/B/C method which shifts a virtual loop coil by a distance shorter than a distance between the two comb portions PT constituting the virtual loop coil, and therefore can increase reception intensity of the pen signals PS near the folding line FL of the foldable display.

In addition, discussed in the present embodiment has been the example which defines the distance (first distance) between the two comb portions PT constituting the virtual loop coil as the distance between the two comb portions PT adjacent to each other with interposition of the one comb portion PT, and defines the shift distance (second distance) of the virtual loop coil as the distance between the two comb portions PT adjacent to each other without interposition of the different comb portion PT. However, the specific values of the first distance and the second distance are not limited to the values specified in the present embodiment as long as the second distance is shorter than the first distance. For example, the first distance may be a distance between the two comb portions PT adjacent to each other with interposition of the two comb portions PT, or a distance between the two comb portions PT with interposition of the three comb portions PT. Moreover, the second distance may be a distance between the two comb portions PT adjacent to each other with interposition of the one comb portion PT, or a distance between the two comb portions PT with interposition of the two comb portions PT.

FIG. 37 is a diagram for explaining a process performed by the sensor controller 31 according to a modification of the present embodiment. The sensor controller 31 according to the present modification is configured to derive a position of the electromagnetic resonance pen 2 on the basis of the summed pen signal PS_{SUM} calculated by calculating a sum of the pen signal PS output from the differential amplifier 50ₓ when the switch circuit 30 is in the first state (hereinafter referred to as “pen signal PS1”), the pen signal PS output from the differential amplifier 50ₓ when the switch circuit 30 is in the second state (hereinafter referred to as “pen signal PS2”), and the pen signal PS output from the differential amplifier 50ₓ when the switch circuit 30 is in the third state (hereinafter referred to as “pen signal PS3”). This applies to the other differential amplifiers 50.

When the switch circuit 30 is in the first state, one virtual loop coil is formed by the comb portions PTₓ₋₂ and PTₓ, and the section included in the base portion PB and connecting these comb portions as described above. In this case, the pen signal PS1 detected by this virtual loop coil is a signal obtained by calculating a sum of the pen signal PS detected by the virtual loop coil constituted by the comb portions PTₓ₋₂ and Ptₓ₋₁, the section included in the base portion PB and connecting these comb portions (hereinafter referred to as “pen signals PS_{x-2, x-1}”), the pen signal PS detected by the virtual loop coil constituted by the comb portions PTₓ₋₁ and PTₓ, and the section included in the base portion PB and connecting these comb portions (hereinafter referred to as “pen signals PS_{x-1, x}”). This applies to the switch circuit 30 in the second state or the third state. Specifically, the pen signal PS2 is a signal obtained by calculating a sum of the pen signals PS_{x-1, x}, the pen signal PS detected by the virtual loop coil constituted by the comb portions PTₓ and PTₓ₊₁, the section included in the base portion PB and connecting these comb portions (hereinafter referred to as “pen signals PS_{x, x+1}”). The pen signal PS3 is a signal obtained by calculating a sum of the pen signals PSₓ and PSₓ₊₁, the pen signal PS detected by the virtual loop coil constituted by the comb portions PTₓ₊₁ and PTₓ₊₂, and the section included in the base portion PB and connecting these comb portions (hereinafter referred to as “pen signals PS_{x+1, x+2}”). Accordingly, as also illustrated in FIG. 37, the summed pen signal PS_{SUM} as a sum of the pen signals PS1 to PS3 is expressed by PS_{x-2, x-1}+2 PS_{x-1, x+}2 PS_{x, x+1}+PS_{x+1, x+2}. This expression is completely equivalent to the expression of the summed pen signal PS_{SUM} discussed in the sixth embodiment. Accordingly, similarly to the position detection system 1 of the sixth embodiment, the position detection system 1 of the present modification offers an advantageous effect of highly accurate detection of the position of the electromagnetic resonance pen 2 even when the electromagnetic resonance pen 2 is tilted with respect to the touch surface 3a.

While the preferred embodiments of the present disclosure have been described above, the present disclosure is not limited to these embodiments in any way. It is obvious that the present disclosure can be practiced in various manners without departing from the spirit of the present disclosure.

1. An integrated circuit connected with a reception coil of an electromagnetic resonance sensor, the reception coil having a plurality of ends along a first side of a touch surface, and the plurality of ends including a first end and a second end, the integrated circuit comprising:
a differential amplifier that has a first input terminal and a second input terminal; and
a switch group that switches a connection destination of the first end between the second input terminal, the second end, a ground terminal, or the first input terminal.

2. The integrated circuit according to claim 1, wherein
the reception coil has a plurality of loop coils that include a first loop coil,
the first end is an end of the first loop coil, and
the switch group, in a case of connecting the first end with the second input terminal, connects another end of the first loop coil with the first input terminal.

3. The integrated circuit according to claim 1, wherein
the reception coil has a plurality of loop coils that include a first loop coil,
the first end is an end of the first loop coil, and
the switch group, in a case of connecting the first end with the ground terminal, connects another end of the first loop coil with the first input terminal, and connects the second input terminal with the ground terminal.

4. The integrated circuit according to claim 1, wherein
the reception coil has a plurality of loop coils that include a first loop coil and a second loop coil disposed adjacent to each other,
the first end is an end of the first loop coil,
the second end is an end of the second loop coil, and
the switch group, in a case of connecting the first end with the second end, connects another end of the first loop coil with the first input terminal, and connects another end of the second loop coil with the second input terminal.

5. The integrated circuit according to claim 1, wherein
the reception coil is a comb-shaped coil that includes a plurality of teeth connected at one ends to a base portion,
the plurality of ends of the reception coil are other ends of the plurality of teeth, and
the switch group switches between a first state of connecting the first end with the second input terminal and a second state of connecting the first end with the first input terminal, in a time-division manner.

6. The integrated circuit according to claim 5, comprising:
a plurality of the differential amplifiers including a first differential amplifier and a second differential amplifier, wherein
the first state is a state of connecting the first end with the second input terminal of the first differential amplifier, and of connecting the second end with the first input terminal of the second differential amplifier, and
the second state is a state of connecting the first end with the first input terminal of the first differential amplifier, and of connecting the second end with the second input terminal of the first differential amplifier.

7. The integrated circuit according to claim 6, wherein,
in the first state, a predetermined number of the ends including the first end are connected with the second input terminal of the first differential amplifier, and the predetermined number of the ends including the second end are connected with the first input terminal of the second differential amplifier, and,
in the second state, the predetermined number of the ends including the first end and the second end are connected with the second input terminal of the first differential amplifier, and the predetermined number of the ends excluding the first end and the second end are connected with the first input terminal of the second differential amplifier.

8. The integrated circuit according to claim 1, wherein an output terminal of the differential amplifier is connected with a sensor controller that detects a position of an electromagnetic resonance pen on a basis of a pen signal output from the differential amplifier.

9.-28. (canceled)
